(19) United States
(12) Patent Application Publication
(10) Pub. No.: US 2026/0096301 A1
(43) Pub. Date: Apr. 2, 2026

(54) DISPLAY PANEL, AND ELECTRONIC DEVICE INCLUDING THE SAME

(71) Applicant: Samsung Display Co., Ltd., Yongin-si (KR)

(72) Inventors: Junsu Park, Yongin-si (KR); Junhyeong Park, Yongin-si (KR)

(21) Appl. No.: 19/267,276

(22) Filed: Jul. 11, 2025

(30) Foreign Application Priority Data
Oct. 2, 2024 (KR) 10-2024-0134274

(51) Int. Cl. H10K 59/123; H10K 59/131; H10K 77/10

(52) U.S. Cl. CPC H10K 59/123; H10K 59/131; H10K 77/111

(57) ABSTRACT

A display panel includes a first pixel circuit layer including a first transistor, a second pixel circuit layer including a second transistor, a first light-emitting diode above the first pixel circuit layer, and electrically connected to the first transistor, a second light-emitting diode above the second pixel circuit layer, and electrically connected to the second transistor, a first line electrically connected to the first transistor, a second line electrically connected to the second transistor, and a connection line electrically connecting the first line to the second line, wherein the first pixel circuit layer and the second pixel circuit layer include insulating layers including an inorganic insulating stack including inorganic insulating layers, and an organic insulating layer above the inorganic insulating stack, and wherein the first line extends across the inorganic insulating stack of the first pixel circuit layer toward the connection line.

### CROSS-REFERENCE TO RELATED APPLICATION

The present application claims priority to, and the benefit of, Korean Patent Application No. 10-2024-0134274, filed on Oct. 2, 2024, in the Korean Intellectual Property Office, the entire disclosure of which is incorporated herein by reference.

### BACKGROUND

### 1. Field

One or more embodiments relate a display panel, a process of manufacturing the display panel, and an electronic device including the display panel.

### 2. Description of the Related Art

Generally, with the development of display panels for visually displaying electrical signals, various display panels with excellent characteristics, such as small thickness, reduced weight, reduced power consumption, etc., and electronic devices including such display panels, have been introduced. For example, display panels having various structures, such as flexible display panels which are foldable or rollable, stretchable display panels, etc., and electronic devices including such display panels have been actively researched and developed.

### SUMMARY

One or more embodiments include a display panel, a process of manufacturing the display panel, and an electronic device including the display panel.

Additional aspects will be set forth in part in the description which follows and, in part, will be apparent from the description, or may be learned by practice of the presented embodiments of the disclosure.

According to one or more embodiments, a display panel includes a base layer including a first surface, and a second surface that is opposite to the first surface, a first pixel circuit layer above the first surface of the base layer, and including a first transistor, a second pixel circuit layer above the first surface of the base layer, apart from the first pixel circuit layer, and including a second transistor, a first light-emitting diode above the first pixel circuit layer, and electrically connected to the first transistor, a second light-emitting diode above the second pixel circuit layer, and electrically connected to the second transistor, a first line electrically connected to the first transistor, a second line electrically connected to the second transistor, and a connection line for electrically connecting the first line to the second line, wherein each of the first pixel circuit layer and the second pixel circuit layer includes insulating layers, the insulating layers comprises an inorganic insulating stack including inorganic insulating layers, and an organic insulating layer above the inorganic insulating stack, and wherein the first line extends across the inorganic insulating stack of the first pixel circuit layer toward the connection line and directly contact the connection line.

A first thickness of a first portion of the base layer overlapping the connection line may be less than a second thickness of a second portion of the base layer overlapping a pixel circuit of the first pixel circuit layer.

The organic insulating layer may include a first organic insulating layer on the inorganic insulating stack of the first pixel circuit layer, and a second organic insulating layer on the first organic insulating layer.

The first organic insulating layer of the first pixel circuit layer may overlap a first contact point of the first line and the connection line.

The organic insulating layer may further include a third organic insulating layer between the inorganic insulating stack and the first organic insulating layer, and covering a side surface of the inorganic insulating stack, wherein a portion of the first line is between the third organic insulating layer and the first organic insulating layer.

A width of the first organic insulating layer may be greater than a width of the inorganic insulating stack.

The first organic insulating layer may contact an upper surface of the connection line.

A first contact point of the first line and the connection line, and a second contact point of the second line and the connection line, may be between the inorganic insulating stack of the first pixel circuit layer and the inorganic insulating stack of the second pixel circuit layer.

A first contact point of the first line and the connection line might not overlap the inorganic insulating stack of the first pixel circuit layer, wherein a second contact point of the second line and the connection line does not overlap the inorganic insulating stack of the second pixel circuit layer.

The display panel may further include a protective layer on the first light-emitting diode and the second light-emitting diode, and directly contacting the connection line.

The protective layer and the base layer may include a same material.

The display panel may further include a first area in which the first pixel circuit layer and the first light-emitting diode are arranged, and having a first elongation, and a second area in which the connection line is arranged, and having a second elongation that is greater than the first elongation.

According to one or more embodiments, an electronic device includes a display panel including a base layer including a first surface, and a second surface that is opposite to the first surface, a first pixel circuit layer above the first surface of the base layer, and including a first transistor and insulating layers, a second pixel circuit layer above the first surface of the base layer, apart from the first pixel circuit layer, and including a second transistor and insulating layers, a first light-emitting diode above the first pixel circuit layer, and electrically connected to the first transistor, a second light-emitting diode above the second pixel circuit layer, and electrically connected to the second transistor, a first line electrically connected to the first transistor, a second line electrically connected to the second transistor, and a connection line electrically connecting the first line to the second line, wherein the insulating layers of each of the first pixel circuit layer and the second pixel circuit layer include an inorganic insulating stack including inorganic insulating layers, and an organic insulating layer above the inorganic insulating stack, and wherein the first line is electrically connected to the connection line through a first contact hole passing through the inorganic insulating stack of the first pixel circuit layer and at least partially filled with a portion of the connection line.

A width of the organic insulating layer of the first pixel circuit layer may be less than or equal to a width of the inorganic insulating stack of the first pixel circuit layer.

The second line may be electrically connected to the connection line through a second contact hole passing through the inorganic insulating stack of the second pixel circuit layer and at least partially filled with another portion of the connection line.

The electronic device may further include a protective layer on the first light-emitting diode and the second light-emitting diode and directly contacting the connection line.

The protective layer and the base layer may include a same material.

The electronic device may further include a first area in which the first pixel circuit layer and the first light-emitting diode are arranged, and having a first elongation, and a second area in which the connection line is arranged, and having a second elongation that is greater than the first elongation.

A first thickness of a first portion of the base layer overlapping the connection line may be less than a second thickness of a second portion of the base layer overlapping a pixel circuit of the first pixel circuit layer.

The connection line may include a first surface contacting the base layer, and a second surface opposite to the first surface and substantially coplanar with the first surface of the base layer.

### BRIEF DESCRIPTION OF THE DRAWINGS

The above and other aspects of embodiments of the disclosure will be more apparent from the following description taken in conjunction with the accompanying drawings, in which:

FIG. 1 is a schematic perspective view of a display panel according to one or more embodiments;

FIGS. 2A and 2B are perspective views of the display panel of FIG. 1 stretched in a first direction;

FIG. 2C is a perspective view of the display panel of FIG. 1 stretched in a second direction;

FIG. 2D is a perspective view of the display panel of FIG. 1 stretched in a first direction and a second direction;

FIG. 2E is a perspective view of the display panel of FIG. 1 stretched in a third direction;

FIG. 3 is a schematic plan view of a display area of a display panel according to one or more embodiments;

FIG. 4 is a cross-sectional view of a first area of FIG. 3;

FIGS. 5A to 5C are each an equivalent circuit diagram of a pixel of a display panel according to one or more embodiments;

FIGS. 6A to 6E are each a schematic cross-sectional view of a light-emitting diode of a display panel according to one or more embodiments;

FIG. 7 is a schematic plan view of a portion of a display area of a display panel according to one or more embodiments;

FIG. 8 is a schematic plan view of a portion of a display area of a display panel according to one or more embodiments;

FIG. 9 is a cross-sectional view of a portion of a display panel according to one or more embodiments;

FIG. 10 is a plan view of the display panel of FIG. 9;

FIG. 11 is a perspective view of a first line, a second line, and a connection line of the display panel of FIG. 9;

FIGS. 12 and 13 are each a cross-sectional view of a portion of a display panel according to one or more embodiments;

FIGS. 14A to 14H are cross-sectional views for describing a process based on a method of manufacturing a display panel, according to one or more embodiments;

FIGS. 15 and 16 are each a cross-sectional view of a portion of a display panel according to one or more embodiments;

FIGS. 17A to 17C are cross-sectional views for describing a process of manufacturing a display panel, according to one or more embodiments;

FIG. 18 is a schematic perspective view of an electronic device according to one or more embodiments, the electronic device including a display panel according to one or more embodiments;

FIG. 19 is a block diagram of an electronic device including a display panel according to one or more embodiments; and

FIGS. 20 and 21 are each a perspective view of an electronic device according to one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” Furthermore, the expression “being the same” may mean “being substantially the same”. In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

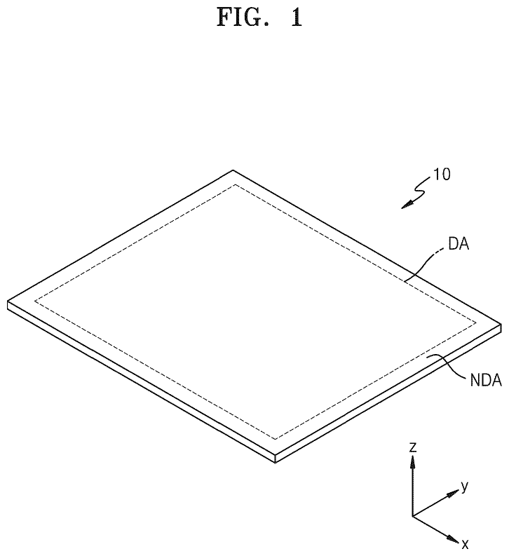

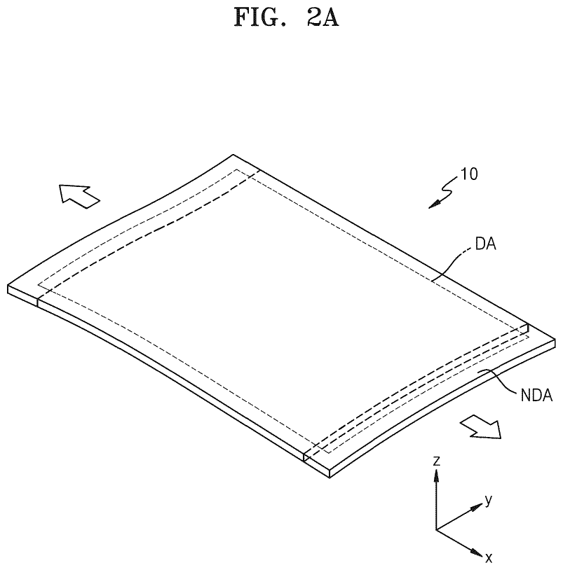

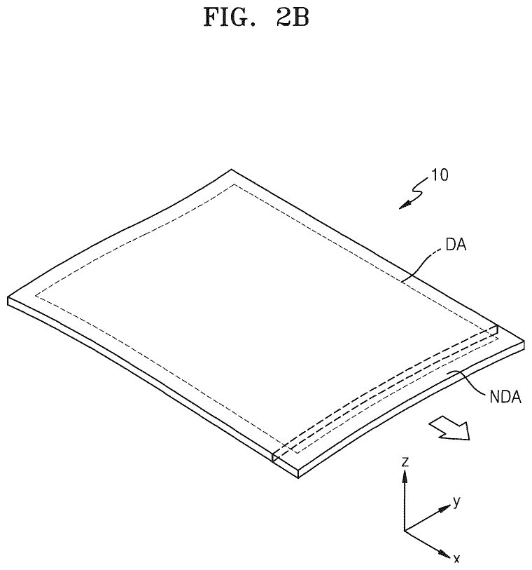

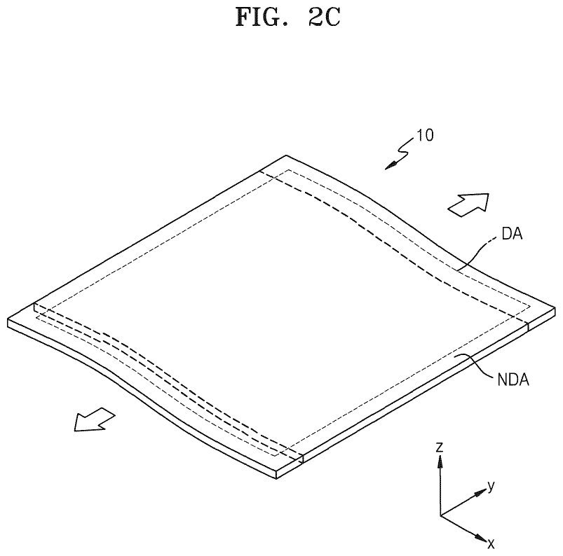

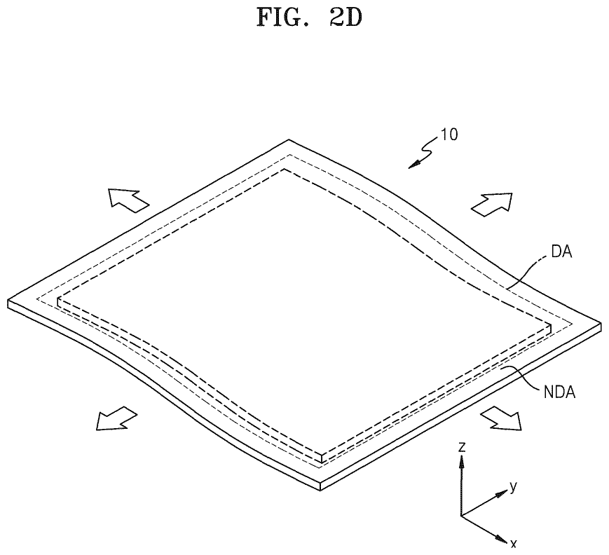

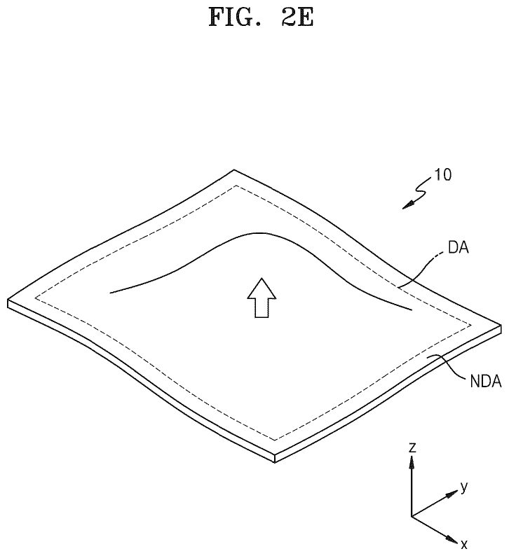

FIG. 1 is a schematic perspective view of a display panel 10 according to one or more embodiments. FIGS. 2A and 2B are perspective views of the display panel 10 of FIG. 1 stretched in a first direction. FIG. 2C is a perspective view of the display panel 10 of FIG. 1 stretched in a second direction. FIG. 2D is a perspective view of the display panel 10 of FIG. 1 stretched in the first direction and the second direction. FIG. 2E is a perspective view of the display panel 10 of FIG. 1 stretched in a third direction.

Referring to FIG. 1, the display panel 10 may include a display area DA and a non-display area NDA. The display area DA may include a plurality of pixels. The display panel 10 may provide a corresponding image by using light emitted from the plurality of pixels. The non-display area NDA may be arranged outside the display area DA. The non-display area NDA may entirely surround the display area DA (e.g., in plan view).

The display panel 10 may be stretched or compressed in various directions. The display panel 10 may be stretched in the first direction (for example, an x direction and/or a-x direction) by an external force applied by an external object or a user.

According to one or more embodiments, as illustrated in FIGS. 2A and 2B, the display area DA and/or the non-display area NDA of the display panel 10 may be stretched in the first direction (for example, the x direction and/or the-x direction). For example, as illustrated in FIG. 2A, the display area DA and/or the non-display area NDA of the display panel 10 may be stretched in the x direction and the-x direction, or as illustrated in FIG. 2B, the display area DA and/or the non-display area NDA of the display panel 10 may be stretched in the x direction with one side of the display panel 10 fixed.

The display panel 10 may be stretched in the second direction (for example, a y direction and/or a-y direction) by an external force applied by an external object or a user. According to one or more embodiments, as illustrated in FIG. 2C, the display area DA and/or the non-display area NDA of the display panel 10 may be stretched in the y direction and the-y direction. According to one or more other embodiments, the display area DA and/or the non-display area NDA of the display panel 10 may be stretched in the y direction and the-y direction with one side of the display panel 10 fixed.

The display panel 10 may be stretched in a plurality of directions, for example, the first direction (for example, the x direction and/or the-x direction) and the second direction (for example, the y direction and/or the-y direction), by an external force applied by an external object or a part of a human body. As illustrated in FIG. 2D, the display area DA and/or the non-display area NDA of the display panel 10 may be stretched in the ±x directions and the ±y directions.

The display panel 10 may be stretched in the third direction (for example, a z direction or a-z direction) by an external force applied by an external object or a part of a human body. According to one or more embodiments, FIG. 2E illustrates that a portion of the display panel 10, for example, a region of the display area DA, may protrude in the z direction. According to one or more other embodiments, a portion of the display panel 10, for example, a region of the display area DA, may protrude in the z direction (or may be recessed in the-z direction).

FIGS. 2A to 2E illustrate that the display panel 10 may be stretched in the first direction, the second direction, and/or the third direction. However, the disclosure is not limited thereto. According to one or more other embodiments, the display panel 10 may be variously deformed to have amorphous shapes, such as a shape that is bent or twisted with respect to two or more axes, etc.

The display panel 10 according to one or more embodiments may be included in a display device for displaying a video or still image, and may be used as a display screen for various products, such as television, laptops, monitors, billboards, Internet of Things (IoTs), as well as portable electronic devices, such as mobile phone, smart phone, smart pad, tablet personal computer (PC), mobile communication terminal, electronic notebook, electronic book, portable multimedia player PMP, personal digital assistant PDA, MP3 player, navigation system, and ultra mobile PC UMPC. In addition, the display panel 10 according to one or more embodiments may be used in wearable devices, such as smart watches, watch phones, glasses-type displays, head-mounted displays HMDs, virtual reality (VR) devices, or augmented reality (AR) devices. In addition, the display panel 10 according to one or more embodiments may be used as a display device of a dashboard of a vehicle, a center information display (CID) disposed in a center fascia or a dashboard of the vehicle, a room mirror display replacing a side mirror of the vehicle, an entertainment element for a rear seat of the vehicle, and a display disposed on a rear surface of the front seat.

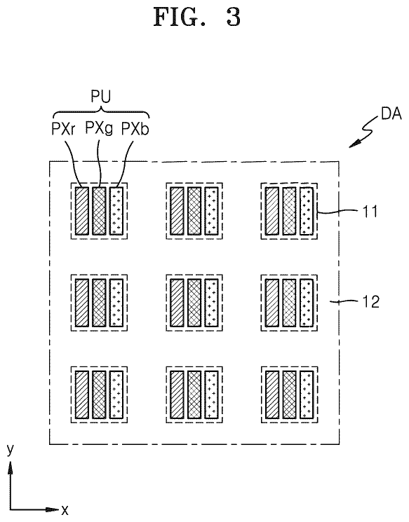

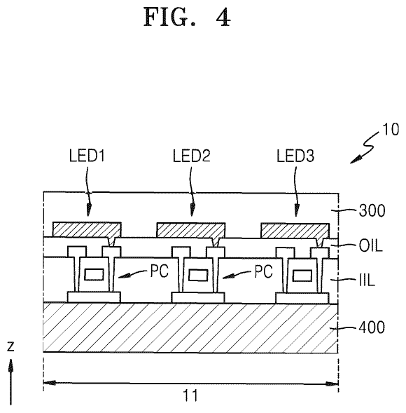

FIG. 3 is a schematic plan view of the display area DA of the display panel 10 according to one or more embodiments, and FIG. 4 is a cross-sectional view of a first area of FIG. 3.

Referring to FIG. 3, the display area DA may include first areas 11 and a second area 12 surrounding each of the first areas 11 (e.g., in plan view). The first areas 11 may be repeatedly arranged in the first direction (for example, the x direction) and the second direction (for example, the y direction).

The display area DA may include the first areas 11 and the second area 12 having different elongations from each other. For example, the display panel 10 may include the first areas 11, each of which has an elongation less than that of the second area, and the second area 12 having an elongation greater than that of the first area 11. In this specification, the elongation may be a numerical value indicating a change ΔL/L in the length by which the display panel 10 may be stretched without being physically damaged, when an external force is applied to the display panel 10. Here, ΔL indicates the amount of change in the length of the display panel 10 and L indicates an initial length of the display panel 10. Thus, the elongation of each of the first area 11 and the second area 12 may indicate the change in the length of each of the first area 11 and the second area 12 when the same external force is applied to each of the first area 11 and the second area 12.

If the elongation of the first area 11 is less than the elongation of the second area 12 may indicate that the first area 11 is relatively less deformed by an external force than the second area 12. Thus, the first areas 11 may be referred to as a low deformation area and the second area 12 may be referred to as a high deformation area.

The first areas 11 may be apart from each other, and may be two-dimensionally arranged in the display area DA. The first area 11 may be where pixels are arranged. Thus, the first area 11 may be referred to as a pixel area or an emission area. One or more pixels may be arranged in each of the first areas 11. A pixel unit PU including a set of pixels may be provided in the first area 11, and each pixel unit PU may include a red pixel PXr, a green pixel PXg, and a blue pixel PXb.

The red pixel PXr, the green pixel PXg, and the blue pixel PXb may include a first light-emitting diode LED1, a second light-emitting diode LED2, and a third light-emitting diode LED3, respectively. Referring to FIG. 4, the first area 11 of the display panel 10 may include a pixel circuit PC arranged on a base layer 400, an inorganic insulating stack IIL, an organic insulating layer OIL, the first to third light-emitting diodes LED1 to LED3 electrically connected to the pixel circuits PC, and a protective layer 300. The elongation of the first area 11 may be relatively less than the elongation of the second area 12, due to a stack structure of the pixel circuits PC, the inorganic insulating stack IIL, the organic insulating layer OIL, and the first to third light-emitting diodes LED1 to LED3 arranged in the first area 11.

The second area 12 may be arranged between the first areas 11 adjacent to each other. As illustrated in FIG. 3, in a plan view, the second area 12 may have the shape surrounding each of the first areas 11. The second area 12 may be where a connection line is arranged, the connection line being configured to connect lines respectively and electrically connected to the pixel circuits PC (see FIG. 4) respectively arranged in the adjacent two first areas 11.

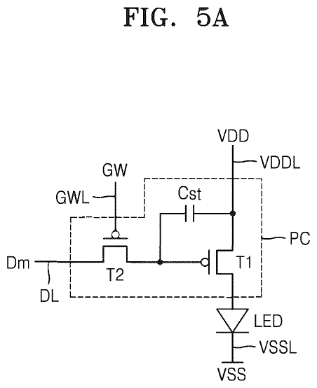

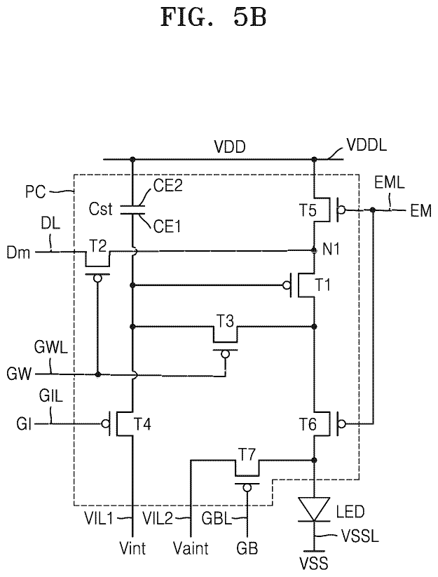

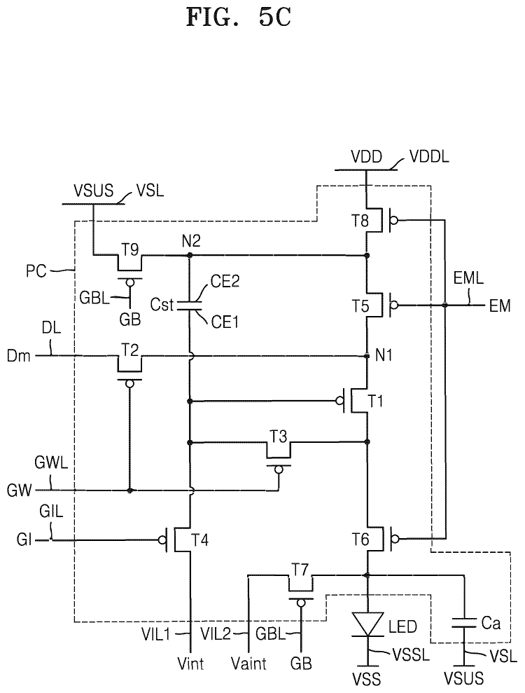

FIGS. 5A to 5C are each an equivalent circuit diagram of a pixel of the display panel 10 according to one or more embodiments.

Referring to FIG. 5A, a light-emitting diode LED corresponding to the pixel may be electrically connected to a pixel circuit PC, and the pixel circuit PC may include a first transistor T1, a second transistor T2, and a storage capacitor Cst. The pixel circuit PC may be electrically connected to a signal line and a voltage line. The signal line may include a scan signal line GWL and a data line DL, and the voltage line may include a first voltage line VDDL.

The second transistor T2 may be electrically connected to the scan signal line GWL and the data line DL. The second signal line GWL may be configured to provide a scan signal GW to a gate electrode of the second transistor T2. The second transistor T2 may be configured to transmit a data signal Dm input from the data line DL to the first transistor T1, according to the scan signal GW input from the scan signal line GWL.

The storage capacitor Cst may be electrically connected to the second transistor T2 and the first voltage line VDDL, and may be configured to store a voltage corresponding to the difference between a voltage transmitted from the second transistor T2 and a first power voltage VDD supplied by the first voltage line VDDL.

The first transistor T1 may include a driving transistor, and may be configured to control a driving current flowing through a light-emitting diode LED. The first transistor T1 may be connected to the first voltage line VDDL and the storage capacitor Cst. The first transistor T1 may be configured to control the driving current flowing from the first voltage line VDDL to the light-emitting diode LED according to a value of the voltage stored in the storage capacitor Cst. The light-emitting diode LED may emit light having a corresponding brightness according to the driving current. A first electrode of the light-emitting diode LED may be electrically connected to the first transistor T1, and a second electrode of the light-emitting element LED may be electrically connected to a second voltage line VSSL configured to supply a second power voltage VSS.

FIG. 5A illustrates that the pixel circuit PC may include two transistors and one storage capacitor. However, according to one or more other embodiments, the pixel circuit PC may include three or more transistors.

Referring to FIG. 5B, the pixel circuit PC may include a first transistor T1, a second transistor T2, a third transistor T3, a fourth transistor T4, a fifth transistor T5, a sixth transistor T6, a seventh transistor T7, and a storage capacitor Cst.

The pixel circuit PC may be electrically connected to signal lines and voltage lines. The signal lines may include gate lines, such as a scan signal line GWL, a bypass control line GBL, an initialization control line GIL, and an emission control line EML, and a data line DL. The voltage lines may include first and second initialization voltage lines VIL1 and VIL2 and a first voltage line VDDL.

The first voltage line VDDL may be configured to transmit a first power voltage VDD to the first transistor T1. The first initialization voltage line VIL1 may be configured to transmit a first initialization voltage Vint for initializing the first transistor T1 to the pixel circuit PC. The second initialization voltage line VIL2 may be configured to transmit a second initialization voltage Vaint for initializing the first electrode of the light-emitting diode LED to the pixel circuit PC.

The first transistor T1 may be electrically connected to the first voltage line VDDL through the fifth transistor T5 and may be electrically connected to the light-emitting diode LED through the sixth transistor T6. The first transistor T1 may function as a driving transistor and may be configured to receive a data signal Dm, and may transmit a driving current to the light-emitting diode LED according to a switching operation of the second transistor T2.

The second transistor T2 may include a data write transistor, and may be electrically connected to the scan signal line GWL and the data line DL. The second transistor T2 may be electrically connected to the first voltage line VDDL through the fifth transistor T5. The second transistor T2 may be turned on according to a scan signal GW received through the scan signal line GWL, and may be configured to perform a switching operation of transmitting the data signal Dm transmitted through the data line DL to a first node N1.

The third transistor T3 may be electrically connected to the scan signal line GWL, and may be electrically connected to the light-emitting diode LED through the sixth transistor T6. The third transistor T3 may be turned on according to a scan signal GW received through the scan signal line GWL, and may be configured to diode-connect the first transistor T1.

The fourth transistor T4 may include a first initialization transistor, and may be electrically connected to the initialization control line GIL and the first initialization voltage line VIL1. The fourth transistor T4 may be turned on according to an initialization control signal GI received through the initialization control line GIL, and may be configured to transmit the first initialization voltage Vint from the first initialization voltage line VIL1 to a gate electrode of the first transistor T1 to initialize a voltage of the gate electrode of the first transistor T1. The initialization control signal GI may correspond to a scan signal of another pixel circuit arranged in a previous row of the corresponding pixel circuit PC.

The fifth transistor T5 may include an operation control transistor, and the sixth transistor T6 may include an emission control transistor. The fifth transistor T5 and the sixth transistor T6 may be electrically connected to the emission control line EML and may be concurrently or substantially simultaneously turned on according to an emission control signal EM received through the emission control line EML to form a current path through which a driving current may flow in a direction from the first voltage line VDDL toward the light-emitting diode LED. The first electrode of the light-emitting diode LED may be electrically connected to the first transistor T1 through the sixth transistor T6, and a second electrode of the light-emitting diode LED may be electrically connected to a second voltage line VSSL configured to supply a second power voltage VSS.

The seventh transistor T7 may include a second initialization transistor and may be electrically connected to the bypass control line GBL, the second initialization voltage line VIL2, and the sixth transistor T6. The seventh transistor T7 may be turned on according to a bypass control signal GB received through the bypass control line GBL, and may be configured to transmit the second initialization voltage Vaint from the second initialization voltage line VIL2 to the first electrode of the light-emitting diode LED to initialize the first electrode of the light-emitting diode LED.

The storage capacitor Cst may include a first electrode CE1 and the second electrode CE2. The first electrode CE1 may be electrically connected to the gate electrode of the first transistor T1, and the second electrode CE2 may be electrically connected to the first voltage line VDDL. The storage capacitor Cst may be configured to store and sustain a voltage corresponding to the difference between a voltage of the first voltage line VDDL and a voltage of the gate electrode of the first transistor T1, so as to sustain a voltage applied to the gate electrode of the first transistor T1.

Referring to FIG. 5C, the pixel circuit PC may include a first transistor T1, a second transistor T2, a third transistor T3, a fourth transistor T4, a fifth transistor T5, a sixth transistor T6, a seventh transistor T7, an eighth transistor T8, a ninth transistor T9, a storage capacitor Cst, and an auxiliary capacitor Ca.

The pixel circuit PC may be electrically connected to signal lines and voltage lines. The signal lines may include gate lines, such as a scan signal line GWL, a bypass control line GBL, an initialization control line GIL, and an emission control line EML, and a data line DL. The voltage lines may include first and second initialization voltage lines VIL1 and VIL2, a sustaining voltage line VSL, and a first voltage line VDDL.

The first voltage line VDDL may be configured to transmit a first power voltage VDD to the first transistor T1. The first initialization voltage line VIL1 may be configured to transmit a first initialization voltage Vint for initializing the first transistor T1 to the pixel circuit PC. The second initialization voltage line VIL2 may be configured to transmit a second initialization voltage Vaint for initializing the first electrode of the light-emitting diode LED to the pixel circuit PC. The sustaining voltage line VSL may be configured to provide a sustaining voltage VSUS to a second node N2, for example, a second electrode CE2 of the storage capacitor Cst, in an initialization section and a data write section.

The first transistor T1 may be electrically connected to the first voltage line VDDL through the fifth transistor T5 and the eighth transistor T8 and may be electrically connected to the light-emitting diode LED through the sixth transistor T6.

The first transistor T1 may function as a driving transistor and may be configured to receive a data signal Dm, and may transmit a driving current to the light-emitting diode LED according to a switching operation of the second transistor T2.

The second transistor T2 may be electrically connected to the scan signal line GWL and the data line DL, and may be electrically connected to the first voltage line VDDL through the fifth transistor T5 and the eighth transistor T8. The second transistor T2 may be turned on according to a scan signal GW received through the scan signal line GWL and may be configured to perform a switching operation of transmitting the data signal Dm transmitted through the data line DL to a first node N1.

The third transistor T3 may be electrically connected to the scan signal line GWL, and may be electrically connected to the light-emitting diode LED through the sixth transistor T6. The third transistor T3 may be turned on according to the scan signal GW received through the scan signal line GWL, and may be configured to diode-connect the first transistor T1 to compensate for a threshold voltage of the first transistor T1.

The fourth transistor T4 may be electrically connected to the initialization control line GIL and the first initialization voltage line VIL1, and may be turned on according to an initialization control signal GI received through the initialization control line GIL, and may be configured to transmit the first initialization voltage Vint from the first initialization voltage line VIL1 to a gate electrode of the first transistor T1 to initialize a voltage of the gate electrode of the first transistor T1. The initialization control signal GI may correspond to a scan signal of another pixel circuit arranged in a previous row of the corresponding pixel circuit PC.

The fifth transistor T5, the sixth transistor T6, and the eighth transistor T8 may be electrically connected to the emission control line EML, and may be concurrently or substantially simultaneously turned on according to an emission control signal EM received through the emission control line EML to form a current path through which a driving current may flow in a direction from the first voltage line VDDL toward the light-emitting diode LED. The first electrode of the light-emitting diode LED may be electrically connected to the first transistor T1 through the sixth transistor T6, and a second electrode of the light-emitting diode LED may be electrically connected to a second voltage line VSSL configured to supply a second power voltage VSS.

The seventh transistor T7 may include a second initialization transistor and may be electrically connected to the bypass control line GBL, the second initialization voltage line VIL2, and the sixth transistor T6. The seventh transistor T7 may be turned on according to a bypass control signal GB received through the bypass control line GBL, and may be configured to transmit the second initialization voltage Vaint from the second initialization voltage line VIL2 to the first electrode of the light-emitting diode LED to initialize the first electrode of the light-emitting diode LED.

The ninth transistor T9 may be electrically connected to the bypass control line GBL, a second electrode CE2 of the storage capacitor Cst, and the sustaining voltage line VSL. The ninth transistor T9 may be turned on according to a bypass control signal GB transmitted through the bypass control line GBL, and may be configured to transmit the sustaining voltage VSUS to a second node N2, for example, the second electrode CE2 of the storage capacitor Cst, in an initialization section and in a data write section.

Each of the eighth transistor T8 and the ninth transistor T9 may be electrically connected to the second node N2, for example, the second electrode CE2 of the storage capacitor Cst. According to some embodiments, in the initialization section and the data write section, the eighth transistor T8 may be turned off, and the ninth transistor T9 may be turned on, and in an emission section, the eighth transistor T8 may be turned on and the ninth transistor T9 may be turned off.

The storage capacitor Cst may include a first electrode CE1 and the second electrode CE2. The first electrode CE1 may be electrically connected to the gate electrode of the first transistor T1, and the second electrode CE2 may be electrically connected to the eighth transistor T8 and the ninth transistor T9.

The auxiliary capacitor Ca may be electrically connected to the sixth transistor T6, to the sustaining voltage line VSL, and to the first electrode of the light-emitting diode LED. The auxiliary capacitor Ca may be configured to store and sustain a voltage corresponding to the difference between voltages of the first electrode of the light-emitting diode LED and the sustaining voltage line VSL, while the seventh transistor T7 and the ninth transistor T9 are being turned on, and thus, the auxiliary capacitor Ca may reduce or prevent an increase in black brightness when the sixth transistor T6 is turned off.

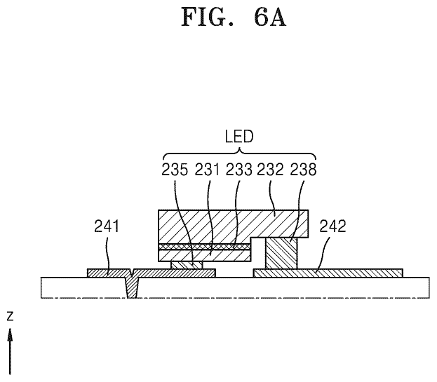

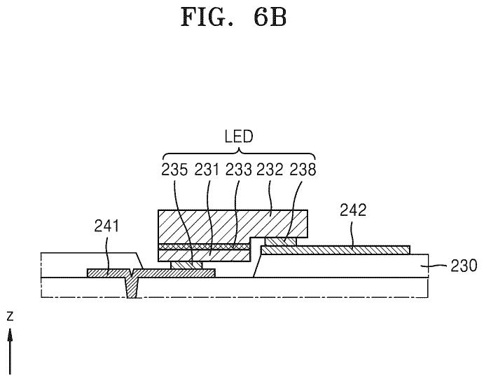

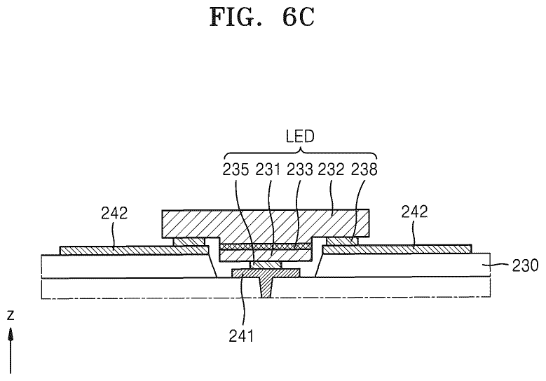

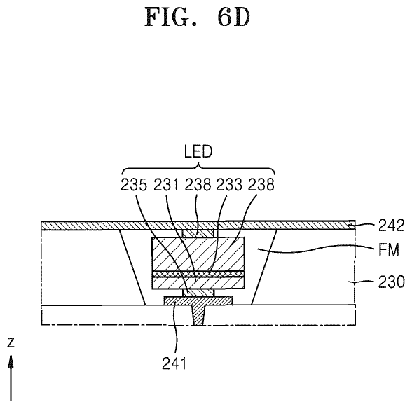

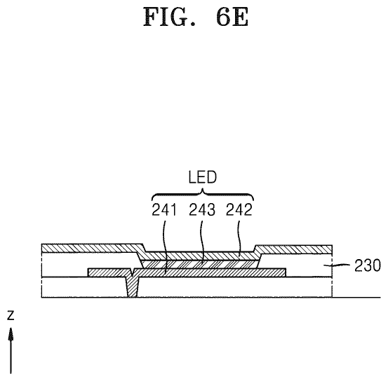

FIGS. 6A to 6E are each a schematic cross-sectional view of the light-emitting diode LED of the display panel 10 according to one or more embodiments.

Referring to FIG. 6A, the light-emitting diode LED may include an inorganic light-emitting diode including an inorganic material. The light-emitting diode LED may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the light-emitting diode LED may be respectively and electrically connected to a first electrode pad 241 and a second electrode pad 242, which are arranged on the same layer. The second electrode pad 242 may be a portion of the second voltage line VSSL (see FIG. 5A) or a conductive layer electrically connected to the second voltage line VSSL (see FIG. 5A).

According to some embodiments, the first semiconductor layer 231 may include a p-type semiconductor layer. The p-type semiconductor layer may include a semiconductor material having a composition of InₓAl_{y}Ga_{1-x-y}N (0≤x≤1, 0≤y≤1, and 0≤x+y≤1), for example, a material selected from among GaN, AlN, AlGaN, InGaN, InN, InAlGaN, AlInN, and/or the like, and may be doped with a p-type dopant, such as Mg, Zn, Ca, Sr, Ba, and the like.

The second semiconductor layer 232 may include, for example, an n-type semiconductor layer. The n-type semiconductor layer may include a semiconductor material having a composition of InₓAl_{y}Ga_{1-x-y}N (0≤x≤1, 0≤y≤1, and 0≤x+y≤1), for example, a material selected from among GaN, AlN, AlGaN, InGaN, InN, InAlGaN, AlInN, and/or the like, and may be doped with an n-type dopant, such as Si, Ge, Sn, and the like.

The intermediate layer 233 may be where electrons and holes reunite, and when the electrons and the holes reunite, there may be transition to a reduced energy level to generate light having a wavelength corresponding to the reduced energy level. The intermediate layer 233 may include, for example, a semiconductor material having a composition of InₓAl_{y}Ga_{1-x-y}N (0≤x≤1, 0≤y≤1, 0≤x+y≤1) and may be formed as a single quantum well structure or a multi-quantum well (MQW) structure. Also, the intermediate layer 233 may include a quantum wire structure or a quantum dot structure.

It is described with reference to FIG. 6A that the first semiconductor layer 231 may include the p-type semiconductor layer, and the second semiconductor layer 232 may include the n-type semiconductor layer. However, the disclosure is not limited thereto. According to one or more other embodiments, the first semiconductor layer 231 may include an n-type semiconductor layer, and the second semiconductor layer 232 may include a p-type semiconductor layer.

FIG. 6A illustrates that the first electrode pad 241 and the second electrode pad 242 may be arranged on the same layer. However, the disclosure is not limited thereto.

Referring to FIG. 6B, the first electrode pad 241 and the second electrode pad 242 may be arranged on different layers. For example, a bank layer 230 having an opening overlapping at least a portion of the first electrode pad 241 may be arranged on the first electrode pad 241, and the second electrode pad 242 may be arranged on an upper surface of the bank layer 230. The structure of the light-emitting diode LED illustrated in FIG. 6B is as described above with reference to FIG. 6A.

According to one or more other embodiments, the second electrode pad 242 may be arranged at both sides of the first electrode pad 241 in a cross-sectional view, as illustrated in FIG. 6C. The bank layer 230 may include an opening overlapping at least a portion of the first electrode pad 241, and the second electrode pad 242 may be arranged around the opening of the bank layer 230. According to some embodiments, the second electrode pad 242 may have a closed-loop shape entirely surrounding the opening of the bank layer 230 and/or the first electrode pad 241 in a plan view. The structure of the light-emitting diode LED illustrated in FIG. 6C is as described above with reference to FIG. 6A.

FIGS. 6A to 6C illustrate that the first electrode 235 and the second electrode 238 of the light-emitting diode LED are arranged in the same direction (for example, a lower direction, that is, a −z direction). However, the disclosure is not limited thereto.

As illustrated in FIG. 6D, the first electrode 235 and the second electrode 238 of the light-emitting diode LED may be arranged in the opposite directions.

The bank layer 230 may include, or may define, an opening exposing at least a portion of the first electrode pad 241, and the thickness of the bank layer 230 may be substantially the same as the thickness of the light-emitting diode LED. The opening of the bank layer 230 may be filled with a filling material FM, and the second electrode pad 242 may be arranged on an upper surface of the bank layer 230 to be electrically connected (for example, in contact) with the second electrode 238 of the light-emitting diode LED. The filling material may include an organic material having an insulating property.

FIGS. 6A to 6D illustrate that the light-emitting diode LED may include an inorganic light-emitting diode including an inorganic material. However, the disclosure is not limited thereto.

Referring to FIG. 6E, the light-emitting diode LED may include an organic light-emitting diode including an organic material. For example, the light-emitting diode LED may include the first electrode pad (or a first electrode) 241, an organic emission layer 243 overlapping the first electrode pad 241 through an opening of the bank layer 230 arranged on the first electrode pad 241, and the second electrode pad (or a second electrode) 242 on the organic emission layer 243. The second electrode pad 242 may be shared by the light-emitting diodes LED. In other words, the second electrode pad 242 of any one light-emitting diode LED may be integrally connected with the second electrode pad 242 of another light-emitting diode LED.

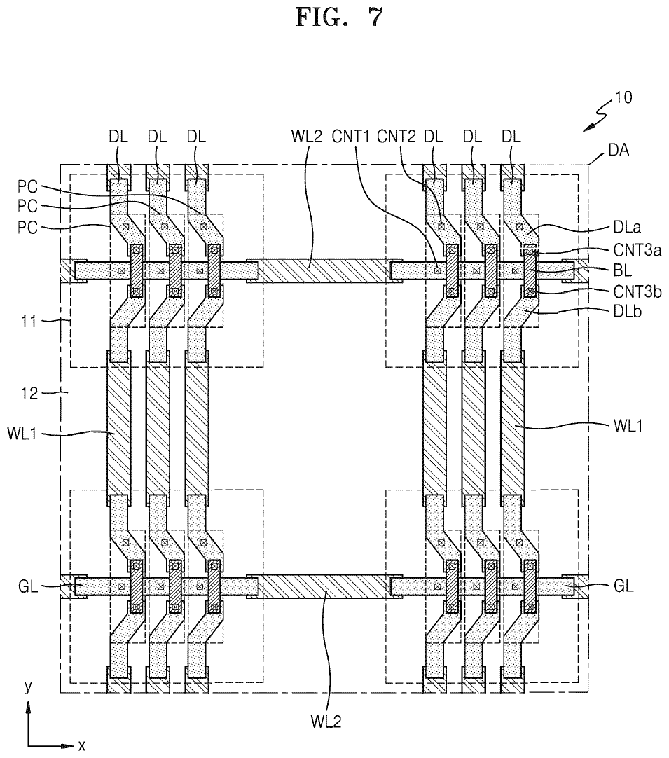

FIG. 7 is a schematic plan view of a portion of the display area DA of the display panel 10 according to one or more embodiments. FIG. 7 illustrates lines electrically connected to the pixel circuits PC arranged in the display area DA.

Referring to FIGS. 3, 4, and 7, the light-emitting diodes corresponding to the pixels PXr, PXg, and PXb of FIG. 3, for example, the first to third light-emitting diodes LED1 to LED3 (see FIG. 4), may be arranged on a structure of the first area 11 illustrated in FIG. 7 and may be understood to be respectively and electrically connected to the pixel circuits PC illustrated in FIG. 7.

Referring to FIG. 7, the pixel circuit PC configured to drive the light-emitting diode of each pixel may be arranged in the first area 11. With respect to this aspect, FIG. 7 illustrates that three pixel circuits PC may be arranged in the first area 11. Each pixel circuit PC may include a transistor and a capacitor, like the pixel circuit PC described above with reference to FIGS. 5A to 5C.

The first area 11 may have an elongation that is less than that of the second area 12. Accordingly, when the display panel 10 is stretched or compressed, the first area 11 may be less deformed than the second area 12. The first area 11 may be referred to as a low deformation area (or a low deformation portion), as described above. Also, the first area 11 may be where the light-emitting diodes are arranged, and may be referred to as a pixel area or an emission area.

The second area 12 may surround the first area 11, and may have a greater elongation than the first area 11. The second area 12 may be where main deformation occurs according to the stretching or shrinkage of a display apparatus. The second area 12 may be arranged between the plurality of first areas 11, and thus, may be referred to as a connection portion connecting the first areas 11. Also, the second area 12 may be referred to as a main deformation area (or a main deformation portion) or a high deformation area (or a high deformation portion). The second area 12 may be where the light-emitting diode is not arranged in the display area DA, and may be referred to as a non-pixel area or a non-emission area.

The lines electrically connected to the pixel circuit PC may be arranged in the display area DA. The lines may include a voltage line or a signal line. According to one or more embodiments, FIG. 7 illustrates that each of the gate line GL and the data line DL is arranged in the first area 11. The gate line GL may be electrically connected to the pixel circuit PC through a first contact hole CNT1. The data line DL may be electrically connected to the pixel circuit PC through the first contact hole CNT1.

The gate line GL of FIG. 7 may be configured to provide a gate signal to a gate electrode of the transistor. According to one or more embodiments, the gate line GL of FIG. 7 may correspond to the scan signal line GWL of FIG. 5A. According to one or more embodiments, the gate line GL of FIG. 7 may correspond to the scan signal line GWL, the bypass control line GBL, the initialization control line GIL, and/or the emission control line EML of FIG. 5B or 5C. The gate line GL extending in a first direction (for example, an x direction) may be electrically connected to the pixel circuits PC arranged in the same row.

The data line DL of FIG. 7 may be configured to provide a data signal to each pixel circuit PC. The data line DL extending in a second direction (for example, a y direction) may be electrically connected to the pixel circuits PC arranged in the same column.

Two data lines DL, which are adjacent to each other and respectively arranged in two first areas 11 that are adjacent to each other, may be electrically connected to each other by a connection line (hereinafter, referred to as a first connection line WL1). The first connection line WL1 may be arranged in the second area 12, and may extend in the second direction (for example, the y direction). Each of the data lines DL arranged at the opposite sides to each other with the first connection line WL1 therebetween may be connected to the first connection line WL1.

Two gate lines GL, which are adjacent to each other and respectively arranged in two first areas 11 that are adjacent to each other, may be electrically connected to each other by a connection line (hereinafter, referred to as a second connection line WL2). The second connection line WL2 may be arranged in the second area 12, and may extend in the first direction (for example, the x direction).

Each of the gate lines GL arranged at the opposite sides to each other with the second connection line WL2 therebetween may be connected to the second connection line WL2.

The gate line GL and the data line DL may cross each other in the first area 11. According to one or more embodiments, the data line DL may include a first portion DLa and a second portion DLb separated from each other with the gate line GL therebetween, and the first portion DLa and the second portion DLb may be electrically connected to each other by a bridge line BL.

The bridge line BL may be arranged where the data line DL and the gate line GL cross each other, and may connect the first portion DLa of the data line DL with the second portion DLb of the data line DL. The bridge line BL may be arranged on a different layer from the first portion DLa and the second portion DLb of the data line DL. An end of the bridge line BL may be connected to the first portion DLa of the data line DL through a third-1 contact hole CNT3a, and the other end of the bridge line BL may be connected to the second portion DLb of the data line DL through a third-2 contact hole CNT3b.

FIG. 7 illustrates that the first portion DLa of the data line DL may be connected to the second portion DLb of the data line DL through the bridge line BL.

However, the disclosure is not limited thereto. According to one or more other embodiments, the gate line GL may be separated into a first portion and a second portion, and the first portion and the second portion of the gate line GL may be connected to each other through the bridge line.

The first and second connection lines WL1 and WL2 arranged in the second area 12 may be more stretchable than the gate line GL and the data line DL arranged in the first area 11. The elongation of each of the first and second connection lines WL1 and WL2 may be greater than the elongation of each of the gate line GL and the data line DL.

Each of the gate line GL and the data line DL may include one or more materials selected from among Al, Pt, Pd, Ag, Mg, Au, Ni, Nd, Ir, Cr, Li, Ca, Mo, Ti, W, and/or Cu. According to some embodiments, each of the gate line GL and the data line DL may include a single layer or a plurality of layers including the metal described above. According to one or more embodiments, each of the gate line GL and the data line DL may include a metal thin layer including a triple layer having a Ti/Al/Ti structure.

The first and second connection lines WL1 and WL2 may include liquid metal or a conductive composite material including a metal nanostructure, an elastic polymer, and/or an elastomer. Thus, when the display panel 10 (see FIG. 1) is stretched, high deformation may occur in the first and second connection lines WL1 and WL2 and the second area 12.

FIG. 7 illustrates that the data line DL and the gate line GL are electrically connected to the first connection line WL1 and the second connection line WL2, respectively. However, the disclosure is not limited thereto. According to one or more other embodiments, each of the first initialization voltage line VIL1, the second initialization voltage line VIL2, the sustaining voltage line VSL, the first voltage line VDDL, and/or the second voltage line VSSL described with reference to FIGS. 5A to 5C may be arranged in the first area 11, and may be electrically connected to the connection line arranged in the second area 12.

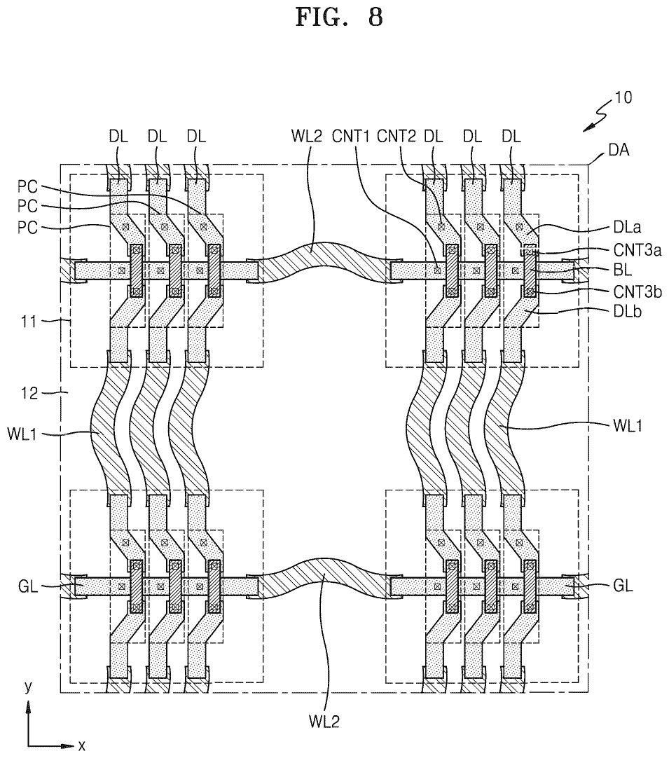

FIG. 8 is a schematic plan view of a portion of the display area DA of the display panel 10 according to one or more embodiments.

FIG. 7 illustrates that the first and second connection lines WL1 and WL2 may be straight or relatively straight in a plan view according to one or more embodiments. However, the disclosure is not limited thereto. As illustrated in FIG. 8, each of the first and second connection lines WL1 and WL2 may have a shape which is not straight in a plan view. The display panel 10 according to one or more embodiments of FIG. 8 may be the same as one or more embodiments described above with reference to FIG. 7, except for the shape of the first and second connection lines WL1 and WL2 in the plan view. Hereinafter, the same aspects are not repeatedly described and the difference is mainly described.

Referring to FIG. 8, each of the first and second connection lines WL1 and WL2 may have a serpentine shape in a plan view. For example, each of the first and second connection lines WL1 and WL2 may have a wave shape having at least two inflection points.

When the first and second connection lines WL1 and WL2 have the serpentine shapes, deformation or damage, which may otherwise occur to the first and second connection lines WL1 and WL2 when the second area 12 is stretched or compressed, may be effectively reduced or prevented.

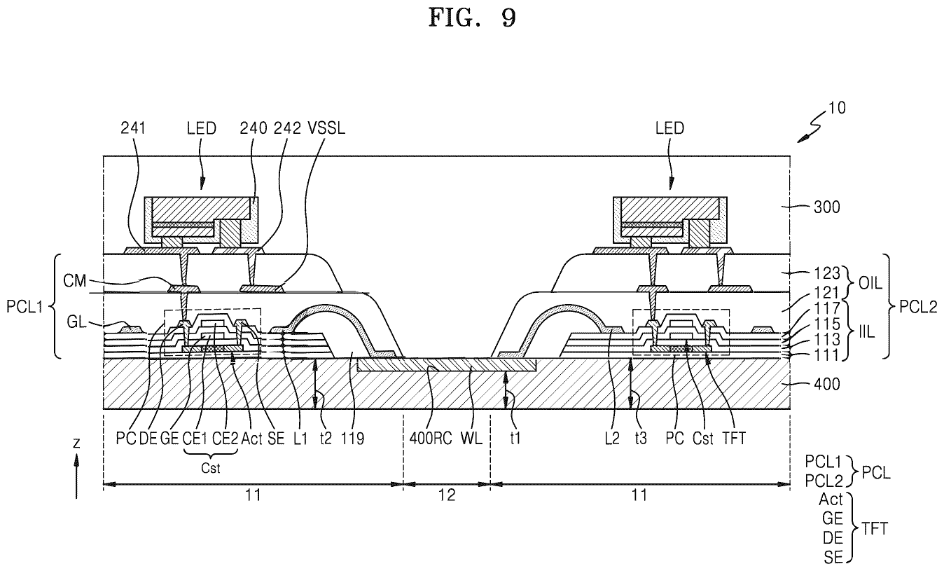

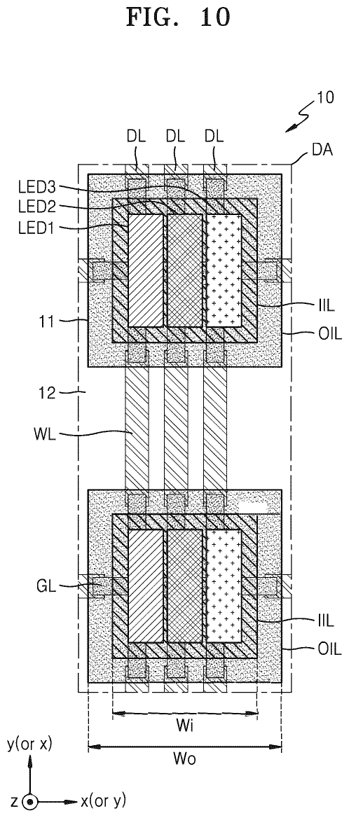

FIG. 9 is a cross-sectional view of a portion of the display panel 10 according to one or more embodiments, and FIG. 10 is a plan view of the display panel 10 corresponding to FIG. 9.

Referring to FIG. 9, the display panel 10 may include the first areas 11, and the second area 12 between the first areas 11 as described above with reference to FIG. 7. The elements of the display panel 10 may be arranged on the base layer 400, and thus, the display panel 10 including the first areas 11 and the second area 12 may mean the base layer 400 may include the first areas 11 and the second area 12.

The display panel 10 may include a pixel circuit layer PCL arranged in each of two first areas 11 adjacent to each other, and a light-emitting diode LED on the pixel circuit layer PCL. The light-emitting diode LED illustrated in FIG. 9 may correspond to any one of the first to third light-emitting diodes LED1 to LED3 illustrated in FIG. 10.

Each pixel circuit layer PCL may include an inorganic insulating stack IIL, a pixel circuit PC, and an organic insulating layer OIL. Hereinafter, for convenience of explanation, one of the pixel circuit layers PCL respectively arranged in the two adjacent first areas 11 may be referred to as a first pixel circuit layer PCL1, and the other may be referred to as a second pixel circuit layer PCL2.

Each of the first pixel circuit layer PCL1 and the second pixel circuit layer PCL2 may be arranged on the base layer 400. Each of the first pixel circuit layer PCL1 and the second pixel circuit layer PCL2 may be arranged on a first surface (for example, an upper surface) of the base layer 400 (as used herein, “arranged on” may mean “above”).

The base layer 400 may absorb the stress occurring when the display panel 10 is stretched. The base layer 400 may include an elastomer. The base layer 400 may include at least one of thermoplastic polyurethane, silicone, thermoplastic rubbers, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomers, ethylene-vinyl acetate, polydimethylsiloxane (PDMS), or Ecoflex™ (Ecoflex™ being a registered trademark of Smooth-On, Inc.).

Each of the first pixel circuit layer PCL1 and the second pixel circuit layer PCL2 may include the inorganic insulating stack IIL, the pixel circuit PC, and the organic insulating layer OIL. The inorganic insulating stack IIL may include a buffer layer 111, a gate-insulating layer 113, a first interlayer insulating layer 115, and a second interlayer insulating layer 117. The organic insulating layer OIL may include a first organic insulating layer 121 and a second organic insulating layer 123.

The first pixel circuit layer PCL1 and the second pixel circuit layer PCL2 may be apart from each other. The first pixel circuit layer PCL1 and the second pixel circuit layer PCL2 being apart from each other may denote that the inorganic insulating stack IIL, the pixel circuit PC, and the organic insulating layer OIL of the first pixel circuit layer PCL1 may be apart from the inorganic insulating stack IIL, the pixel circuit PC, and the organic insulating layer OIL of the second pixel circuit layer PCL2.

The inorganic insulating stack IIL may be arranged in the first area 11, and may not be arranged in, or may be omitted from, the second area 12. As illustrated in FIG. 10, the inorganic insulating stack IIL may be arranged in the first area 11 in an isolated shape. The inorganic insulating stacks IIL arranged in the first areas 11 may be apart from each other in a plan view. For example, the buffer layer 111, the gate-insulating layer 113, the first interlayer insulating layer 115, and the second interlayer insulating layer 117 of the first pixel circuit layer PCL1 may be respectively separated from the buffer layer 111, the gate-insulating layer 113, the first interlayer insulating layer 115, and the second interlayer insulating layer 117 of the second pixel circuit layer PCL2.

Likewise, the organic insulating layer OIL may be arranged in the first area 11 and may not be arranged in the second area 12. As illustrated in FIG. 10, the organic insulating layer OIL may be arranged in the first area 11 in an isolated shape. For example, the first organic insulating layer 121 and the second organic insulating layer 123 of the first pixel circuit layer PCL1 may be respectively separated from the first organic insulating layer 121 and the second organic insulating layer 123 of the second pixel circuit layer PCL2.

As illustrated in FIG. 9, the buffer layer 111 may be arranged on the base layer 400, and the pixel circuit PC may be arranged on the buffer layer 111. The buffer layer 111 may include an inorganic insulating material, such as silicon oxide, silicon nitride, and silicon oxynitride.

A thin-film transistor TFT of the pixel circuit PC may include a semiconductor layer Act, a gate electrode GE, a source electrode SE, and a drain electrode DE. FIG. 9 illustrates a top-gate type in which the gate electrode GE is arranged on (e.g., above) the semiconductor layer Act with the gate-insulating layer 113 therebetween.

However, according to one or more other embodiments, the thin-film transistor TFT may include a bottom-gate type.

The semiconductor layer Act may include polysilicon. Alternatively, the semiconductor layer Act may include amorphous silicon, an oxide semiconductor, an organic semiconductor, or the like. The gate electrode GE may include a metal thin layer including a low-resistance metal material. The gate electrode GE may include a conductive material including Mo, Al, Cu, Ti, or the like, and may include layers or a single layer including the materials described above. For example, the gate electrode GE may include a metal thin layer including a triple layer having a Ti/Al/Ti structure.

The gate-insulating layer 113 between the semiconductor layer Act and the gate electrode GE may include an inorganic insulating material, such as silicon oxide, silicon nitride, silicon oxynitride, aluminum oxide, titanium oxide, etc. The gate-insulating layer 113 may include a single layer or layers including the materials described above.

The source electrode SE and the drain electrode DE may be arranged on the same layer, for example, the second interlayer insulating layer 117, and may include the same material. The source electrode SE and the drain electrode DE may include a metal thin layer including a low-resistance metal material. The source electrode SE and the drain electrode DE may include a conductive material including Mo, Al, Cu, Ti, or the like and may include layers or a single layer including the materials described above. For example, the source electrode SE and the drain electrode DE may include a metal thin layer including a triple layer having a Ti/Al/Ti structure, like the gate electrode GE. The second interlayer insulating layer 117 may include an inorganic insulating material, such as silicon oxide, silicon nitride, silicon oxynitride, aluminum oxide, titanium oxide, etc., and may include a single layer or multiple layers including the materials described above.

The storage capacitor Cst may include a first electrode CE1 and a second electrode CE2 overlapping each other with the first interlayer insulating layer 115 therebetween. The storage capacitor Cst may overlap the thin-film transistor TFT. With respect to this aspect, FIG. 9 illustrates that the gate electrode GE of the thin-film transistor TFT may correspond to the first electrode CE1 of the storage capacitor Cst. According to one or more other embodiments, the storage capacitor Cst may not overlap the thin-film transistor TFT. The storage capacitor Cst may be covered by the second interlayer insulating layer 117.

The first interlayer insulating layer 115 may be arranged between the gate-insulating layer 113 and the second interlayer insulating layer 117. Each of the first interlayer insulating layer 115 and the second interlayer insulating layer 117 may include an inorganic insulating material, such as silicon oxide, silicon nitride, silicon oxynitride, aluminum oxide, titanium oxide, etc., and may include a single layer or layers including the materials described above.

The second electrode CE2 of the storage capacitor Cst may include a conductive material, and may include layers or a single layer. The second electrode CE2 may include a metal thin layer including a low-resistance metal material. The second electrode CE2 may include a conductive material including Mo, Al, Cu, Ti, or the like, and may include layers or a single layer including the materials described above. For example, the second electrode CE2 may include a metal thin layer including a triple layer having a Ti/Al/Ti structure.

The first organic insulating layer 121 may be arranged on the second interlayer insulating layer 117. The second organic insulating layer 123 may be arranged on the first organic insulating layer 121. A connection electrode CM and the second voltage line VSSL may be arranged on the first organic insulating layer 121. The connection electrode CM may electrically connect the pixel circuit PC with the first electrode pad 241. The second voltage line VSSL may be electrically connected to the second electrode pad 242.

The connection electrode CM and the second voltage line VSSL may include a metal thin layer including a low-resistance metal material. The connection electrode CM and the second voltage line VSSL may include a conductive material including Mo, Al, Cu, Ti, or the like and may include layers or a single layer including the materials described above. For example, the connection electrode CM and the second voltage line VSSL may include a metal thin layer including a triple layer having a Ti/Al/Ti structure.

The first electrode pad 241 and the second electrode pad 242 may be arranged on the second organic insulating layer 123. The first electrode pad 241 may be electrically connected to the thin-film transistor TFT through the connection electrode CM between the first organic insulating layer 121 and the second organic insulating layer 123.

The light-emitting diode LED on the first electrode pad 241 and the second electrode pad 242 may be the same as the light-emitting diode LED described above with reference to FIG. 6A. According to one or more other embodiments, the light-emitting diode LED may have the structure as illustrated in FIGS. 6B to 6D. A surface of the light-emitting diode LED may be covered by a protective material layer 240 including an organic insulating material.

A first line L1 may include a signal line or a voltage line electrically connected to the pixel circuit PC of the first pixel circuit layer PCL1. A second line L2 may include a signal line or a voltage line electrically connected to the pixel circuit PC of the second pixel circuit layer PCL2. According to one or more embodiments, the first line L1 and the second line L2 may include the gate line GL (see FIG. 7) or the data line DL (see FIG. 7) described above with reference to FIG. 7. According to one or more other embodiments, the first line L1 and the second line L2 may include the first voltage line VDDL or the second voltage line VSSL described with reference to FIG. 5A or the first initialization voltage line VIL1, the second initialization voltage line VIL2, the sustaining voltage line VSL, the first voltage line VDDL, or the second voltage line VSSL described with reference to FIGS. 5B and 5C.

Each of the first line L1 and the second line L2 may be arranged on the second interlayer insulating layer 117, and may extend onto a connection line WL. One portion of the first line L1 may be arranged on a corresponding portion of the second interlayer insulating layer 117. Another portion of the first line L1 may extend across the inorganic insulating stack IIL onto the connection line WL, and may directly contact the connection line WL. In a direction (e.g., a z direction) perpendicular to the upper surface of the base layer 400, the one portion of the first line L1 described above may be arranged between the corresponding portion of the second interlayer insulating layer 117 and a corresponding portion of the first organic insulating layer 121, and the other portion of the first line L1 described above may be arranged between the connection line WL and a corresponding portion of the first organic insulating layer 121. One portion of the second line L2 may be arranged on a corresponding portion of the second interlayer insulating layer 117, and another portion of the second line L2 may extend onto the connection line WL and may directly contact the connection line WL. In the direction (e.g., the z direction) perpendicular to the upper surface of the base layer 400, the one portion of the second line L2 described above may be arranged between the corresponding portion of the second interlayer insulating layer 117 and a corresponding portion of the first organic insulating layer 121, and the other portion of the second line L2 described above may be arranged between the connection line WL and a corresponding portion of the first organic insulating layer 121.

The inorganic insulating stack IIL having the isolated shape in the plan view may have a step difference with respect to the upper surface of the base layer 400, as illustrated in FIG. 9. According to one or more embodiments, as illustrated in FIG. 9, the organic insulating layer OIL may further include a third organic insulating layer 119 arranged to cover a side surface of the inorganic insulating stack IIL. The third organic insulating layer 119 may have a closed loop shape in a plan view to cover the side surface of the inorganic insulating stack IIL.

The first line L1 and the second line L2 may extend across an upper surface of the third organic insulating layer 119 onto the connection line WL. In the cross-sectional view of FIG. 9, a first thickness t1 of a first portion of the base layer 400 overlapping the connection line WL may be less than a thickness of another portion of the base layer 400 not overlapping the connection line WL. For example, the first thickness t1 of the first portion of the base layer 400 overlapping the connection line WL may be less than a second thickness t2 of a second portion of the base layer 400 overlapping the inorganic insulating stack IIL or the pixel circuit PC of the first pixel circuit layer PCL1. The first thickness t1 of the first portion of the base layer 400 overlapping the connection line WL may be less than a third thickness t3 of a third portion of the base layer 400 overlapping the inorganic insulating stack IIL or the pixel circuit PC of the second pixel circuit layer PCL2.

The base layer 400 may include the first surface (for example, the upper surface) toward or facing the first pixel circuit layer PCL1 and the second pixel circuit layer PCL2, and a second surface (for example, a lower surface) that is the opposite to the first surface. The base layer 400 may include a recess 400RC that is concave with respect to the first surface, and the connection line WL may be arranged in the recess 400RC. For example, the connection line WL may fill the recess 400RC. In other words, the volume of the connection line WL may be substantially the same as the volume of the recess 400RC. As described above, the connection line WL may be embedded in the base layer 400, and thus, the stress that may be concentrated in the connection line WL when the display panel 10 is stretched, may be absorbed by the base layer 400.

The connection line WL may include a first surface (for example, a lower surface) facing toward the base layer 400, and a second surface (for example, an upper surface) that is the opposite to the first surface. The second surface (for example, the upper surface) of the connection line WL may be coplanar with the first surface (for example, the upper surface) of the base layer 400. The first surface (for example, the lower surface) of the connection line WL may be arranged between the first surface (for example, the upper surface) of the base layer 400 and the second surface (for example, the lower surface) of the base layer 400.

As illustrated in FIG. 10, each of the inorganic insulating stack IIL and the organic insulating layer OIL may be arranged in the first area 11 in an isolated shape. The first area 11 may be defined by projecting the inorganic insulating stack IIL and the organic insulating layer OIL in a direction perpendicular to the base layer 400. The second area 12, in which the inorganic insulating stack IIL and the organic insulating layer OIL are omitted, may be suitably or relatively easily deformed.

According to one or more embodiments, the inorganic insulating stack IIL and the organic insulating layer OIL overlapping each other may have different widths. For example, as illustrated in FIG. 10, a width Wi of the inorganic insulating stack IIL may be less than a width Wo of the organic insulating layer OIL. With respect to this aspect, FIG. 9 illustrates that the first organic insulating layer 121 corresponding to the first pixel circuit layer PCL1 may extend across the side surface of the inorganic insulating stack IIL toward a first contact point between the first line L1 and the connection line WL. Similarly, the first organic insulating layer 121 corresponding to the second pixel circuit layer PCL2 may extend across the side surface of the inorganic insulating stack IIL toward a second contact point of the second line L2 and the connection line WL.

The first contact point of the first line L1 and the connection line WL, and the second contact point of the second line L2 and the connection line WL, may be arranged between the inorganic insulating stack IIL of the first pixel circuit layer PCL1 and the inorganic insulating stack IIL of the second pixel circuit layer PCL2. In one or more embodiments, the first contact point of the first line L1 and the connection line WL may not overlap the inorganic insulating stack IIL of the first pixel circuit layer PCL1, and the second contact point of the second line L2 and the connection line WL may not overlap the inorganic insulating stack IIL of the second pixel circuit layer PCL2.

The first organic insulating layer 121 corresponding to the first pixel circuit layer PCL1 may overlap the first contact point of the first line L1 and the connection line WL. Similarly, the first organic insulating layer 121 corresponding to the second pixel circuit layer PCL2 may overlap the second contact point of the second line L2 and the connection line WL. The first organic insulating layer 121 of each of the first pixel circuit layer PCL1 and the second pixel circuit layer PCL2 may be in contact with the upper surface of the connection line WL.

The light-emitting diode LED may be arranged on the corresponding pixel circuit layer PCL. For example, the light-emitting diode LED electrically connected to the pixel circuit PC of the first pixel circuit layer PCL1 may be arranged on the corresponding first pixel circuit layer PCL1, and the light-emitting diode LED electrically connected to the pixel circuit PC of the second pixel circuit layer PCL2 may be arranged on the corresponding second pixel circuit layer PCL2. A surface of each light-emitting diode LED may be covered by the protective material layer 240. The protective material layer 240 may include an organic insulating material such as polyimide.

The protective layer 300 may be arranged on the light-emitting diode LED and the connection line WL. The protective layer 300 may cover the light-emitting diode LED and the connection line WL. The protective layer 300 may absorb stress, which otherwise may be transmitted to the light-emitting diode LED and the connection line WL when the display panel 10 is stretched, and may planarize an upper surface of the display panel 10. The protective layer 300 may include an elastomer. For example, the protective layer 300 may include at least one of thermoplastic polyurethane, silicone, thermoplastic rubbers, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomers, ethylene-vinyl acetate, PDMS, or Ecoflex™ (Ecoflex™ being a registered trademark of Smooth-On, Inc.).

The protective layer 300 may directly contact the upper surface of the connection line WL, and may directly contact a portion of the upper surface of the base layer 400. According to one or more embodiments, when the protective layer 300 and the base layer 400 include the same material, the adhesion force of the protective layer 300 and the base layer 400 may be increased, and thus, the adhesion of the display panel 10 may be further effectively maintained.

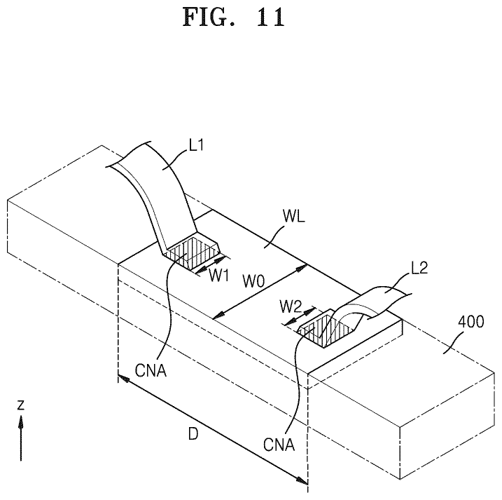

FIG. 11 is a perspective view of the first line L1, the second line L2, and the connection line WL of FIG. 9.

Referring to FIG. 11, the connection line WL may be embedded in the base layer 400, and each of the first line L1 and the second line L2 may extend onto the connection line WL, and may directly contact the second surface (for example, the upper surface) of the connection line WL. A layer may not be arranged between the first line L1 and the connection line WL or between the second line L2 and the connection line WL. Thus, a contact area CNA of the first line L1 and the connection line WL may be the same as the area of a bottom surface of a portion of the first line L1 meeting the upper surface of the connection line WL, and a contact area CNA of the second line L2 and the connection line WL may be the same as the area of a bottom surface of a portion of the second line L2 meeting the upper surface of the connection line WL.

The connection line WL may have a length D in a direction from the first line L1 toward the second line L2, and may have a width W0 in a direction perpendicular to the length D described above. To sufficiently obtain the contact area CNA, the width W0 of the connection line WL may be greater than a width W1 of the first line L1 and/or a width W2 of the second line L2.

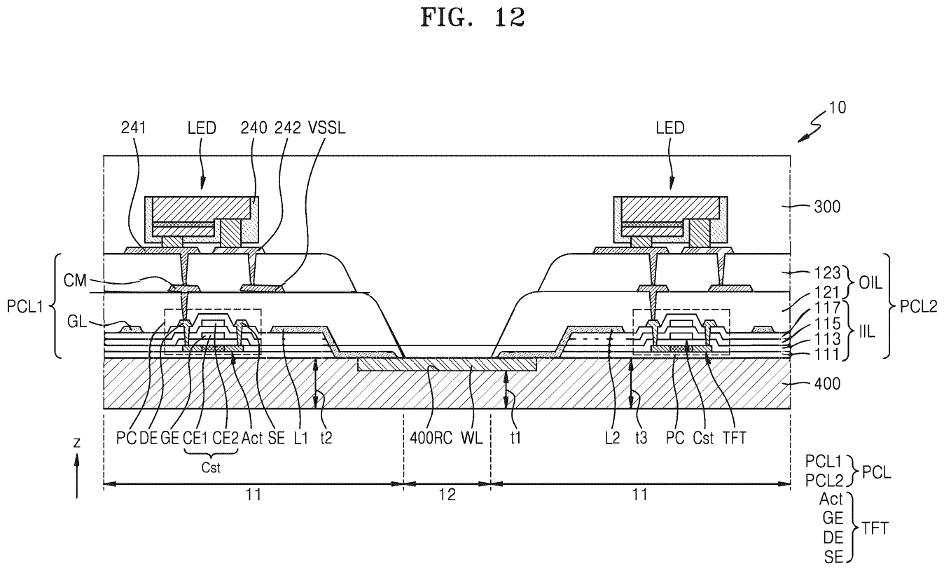

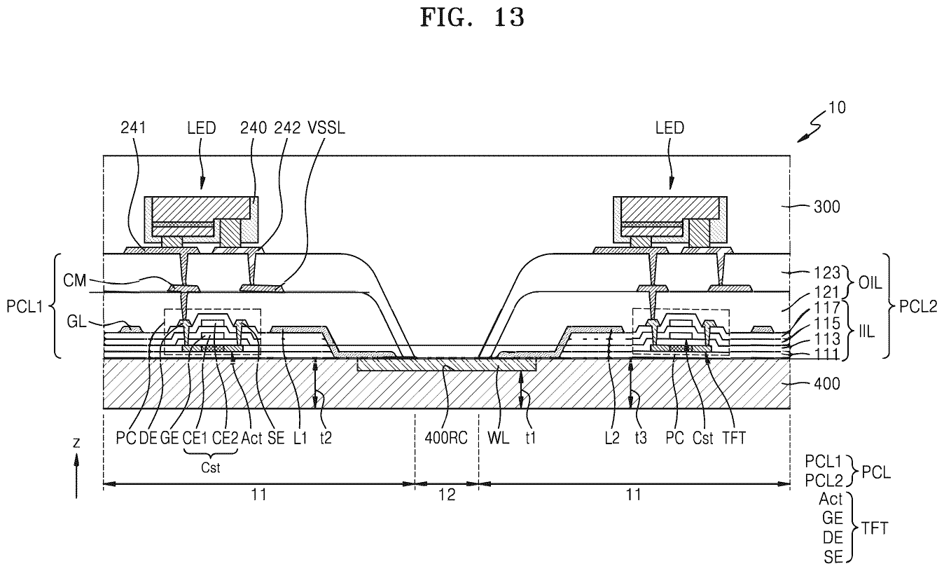

FIGS. 12 and 13 are each a cross-sectional view of a portion of the display panel 10 according to one or more embodiments.

The organic insulating layer OIL of the display panel 10 according to one or more embodiments described with reference to FIG. 9 may include the third organic insulating layer 119 covering the side surface of the inorganic insulating stack IIL. However, the disclosure is not limited thereto. The organic insulating layer OIL of the display panel 10 according to embodiments of FIGS. 12 and 13 may not include the third organic insulating layer 119. The display panel 10 according to embodiments of FIGS. 12 and 13 may have substantially the same structure as described with reference to FIG. 9, and thus, hereinafter, different aspects are mainly described.

Referring to FIGS. 12 and 13, the first line L1 may extend onto the connection line WL while being in contact with the side surface of the corresponding inorganic insulating stack IIL, and the second line L2 may extend onto the connection line WL while being in contact with the side surface of the corresponding inorganic insulating stack IIL. The first organic insulating layer 121 of the first pixel circuit layer PCL1 may have a greater width than the inorganic insulating stack IIL. The first organic insulating layer 121 may cover the first contact point of the first line L1 and the connection line WL. Likewise, the first organic insulating layer 121 of the second pixel circuit layer PCL2 may have a greater width than the inorganic insulating stack IIL. The first organic insulating layer 121 may cover the second contact point of the second line L2 and the connection line WL.

As illustrated in FIG. 12, the second organic insulating layer 123 may not extend across a side surface of the first organic insulating layer 121 toward the connection line WL, or as illustrated in FIG. 13, the second organic insulating layer 123 may extend across the side surface of the first organic insulating layer 121 toward the connection line WL. According to one or more embodiments, as illustrated in FIG. 12, a side surface of the second organic insulating layer 123 may meet an upper surface of the first organic insulating layer 121. According to one or more other embodiments, as illustrated in FIG. 13, the second organic insulating layer 123 may cover the side surface of the first organic insulating layer 121, and may be in contact with a portion of the upper surface of the connection line WL.

The structure of the second organic insulating layer 123 described with reference to FIG. 13 may be applied to FIG. 9. For example, the second organic insulating layer 123 illustrated in FIG. 9 may extend so as to be in contact with a portion of the upper surface of the connection line WL, like the second organic insulating layer 123 of FIG. 13.

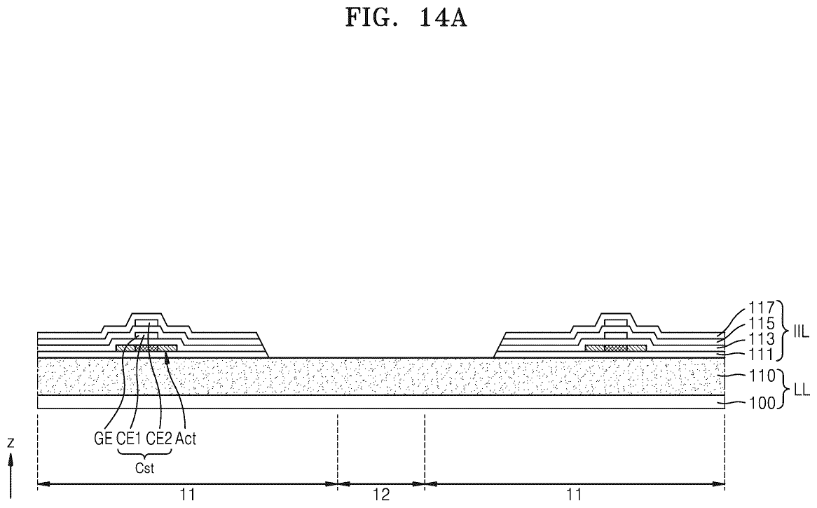

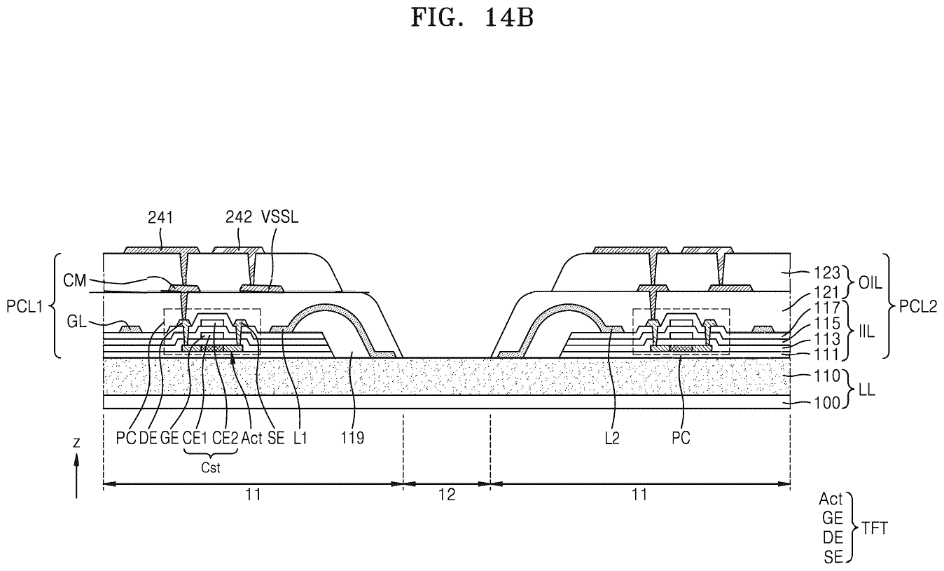

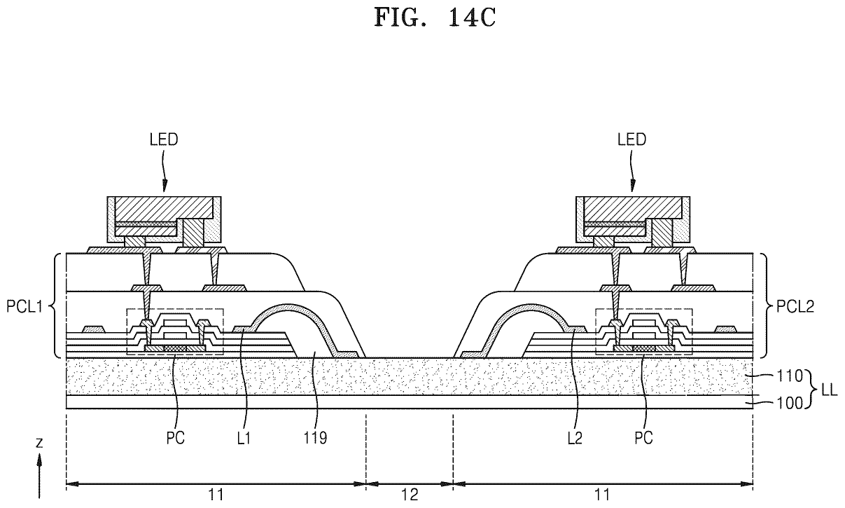

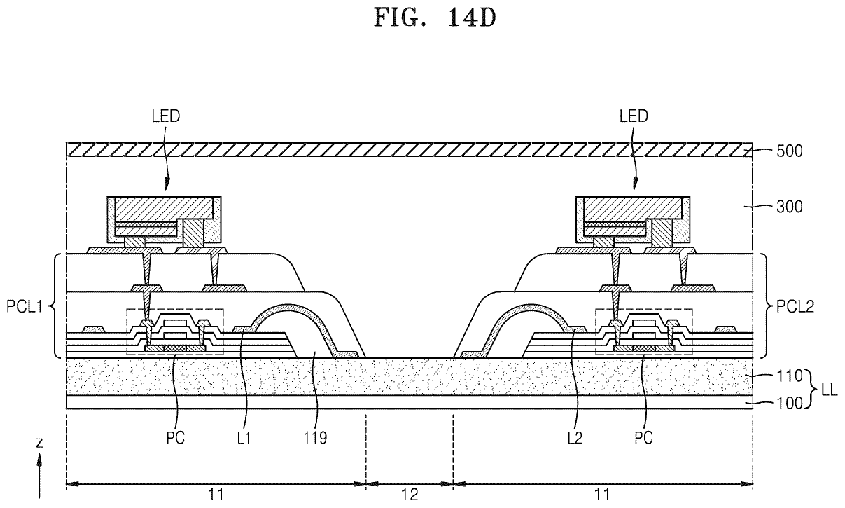

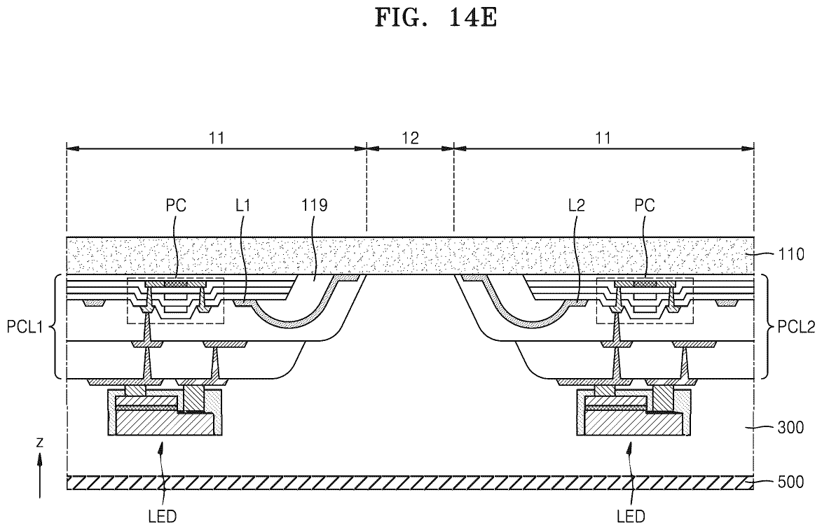

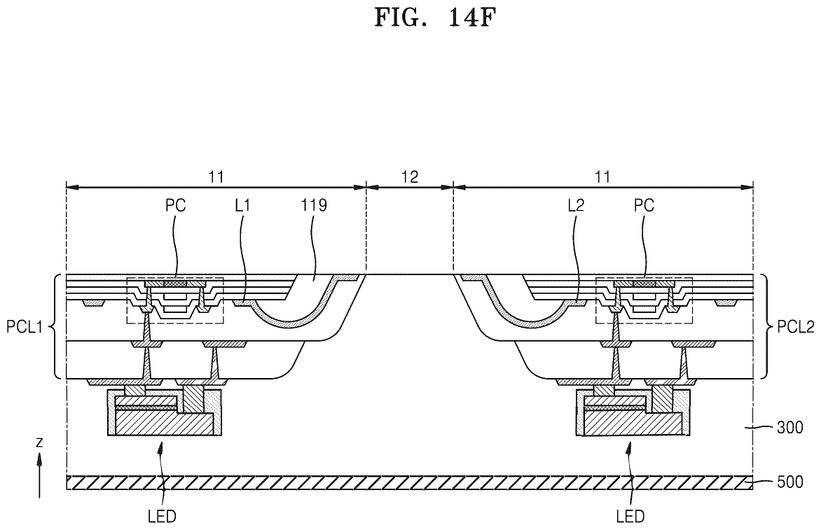

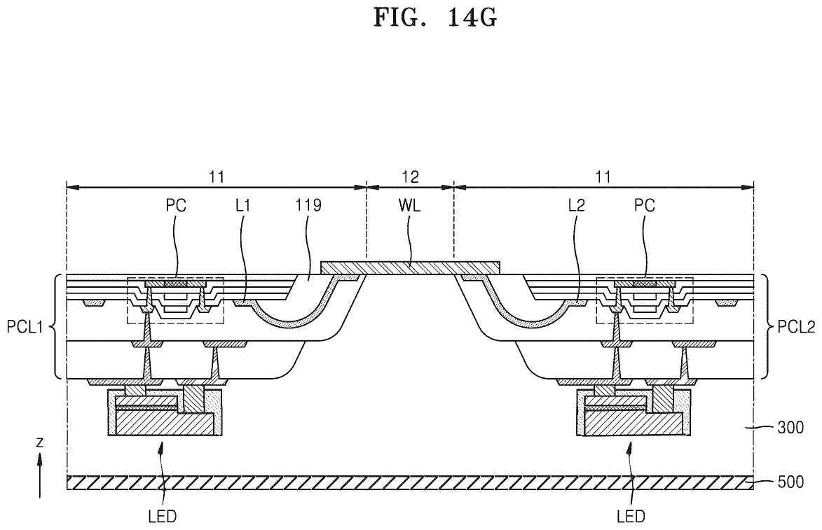

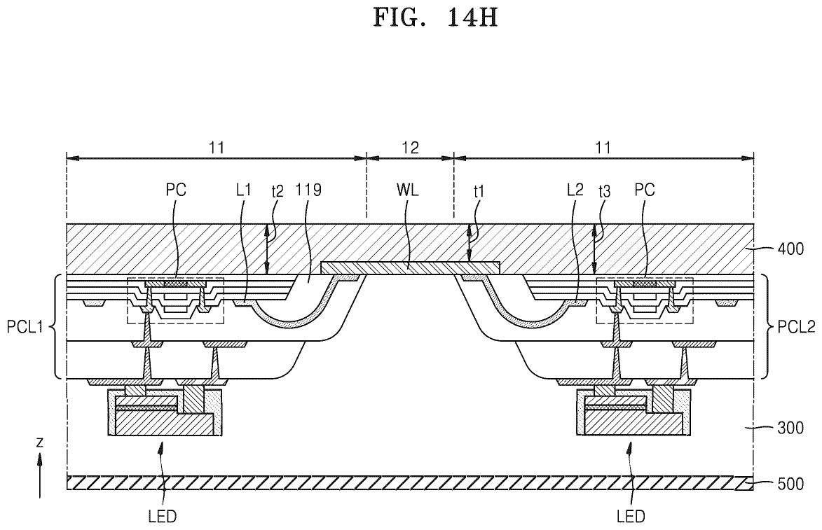

FIGS. 14A to 14H are cross-sectional views for describing a process according to a method of manufacturing the display panel 10, according to one or more embodiments.

Referring to FIG. 14A, a carrier layer LL may be prepared. According to one or more embodiments, the carrier layer LL may include a substrate 100, and a resin layer 110 arranged on the substrate 100. The substrate 100 may include a rigid substrate. For example, the substrate 100 may include a transparent glass substrate mainly including SiO₂ or a substrate including a polymer resin material, such as tempered plastic. The resin layer 110 may include polymer resins. For example, the resin layer 110 may include polyether sulfone, polyacrylate, polyether imide, polyethylene naphthalate, polyethylene terephthalate, polyphenylene sulfide, polyarylate, polyimide, polycarbonate, cellulose acetate propionate, or the like. According to one or more embodiments, the thickness of the resin layer 110 may be greater than the thickness of the substrate 100.

The inorganic insulating stack IIL, the storage capacitor Cst, and a portion of the thin-film transistor TFT (see FIG. 9) may be formed on the carrier layer LL. For example, the buffer layer 111, the semiconductor layer Act, the gate-insulating layer 113, the gate electrode GE, the first interlayer insulating layer 115, the second electrode CE2, and the second interlayer insulating layer 117 may be formed on the carrier layer LL.

The inorganic insulating stack IIL may be arranged only in the first area 11, and may not be arranged in/may be omitted from the second area 12. For example, a portion of the inorganic insulating stack IIL overlapping the second area 12 may be removed by an etching process.

Referring to FIG. 14B, the third organic insulating layer 119 may be formed on the second interlayer insulating layer 117. The third organic insulating layer 119 may cover a side surface of the inorganic insulating stack IIL. The source electrode SE and the drain electrode DE may be formed on the second interlayer insulating layer 117.

The first line L1 and the second line L2 may be formed. The first line L1 may be arranged on the corresponding second interlayer insulating layer 117, and may extend across an upper surface of the third organic insulating layer 119 onto an upper surface of the resin layer 110. The second line L2 may be arranged on the corresponding second interlayer insulating layer 117, and may extend across the upper surface of the third organic insulating layer 119 onto a first surface (for example, a surface facing the buffer layer 111) of the resin layer 110.

The first organic insulating layer 121 may be formed on the pixel circuit PC, and the connection electrode CM and the second voltage line VSSL may be formed on the first organic insulating layer 121. The second organic insulating layer 123 may be formed on the connection electrode CM, and the first electrode pad 241 and the second electrode pad 242 may be formed on the second organic insulating layer 123.

FIG. 14B illustrates a structure in which the third organic insulating layer 119 is formed. However, the disclosure is not limited thereto. According to one or more other embodiments, the third organic insulating layer 119 may not be formed, or may be omitted, as illustrated in FIGS. 12 and 13, and when the third organic insulating layer 119 is not formed, each of the first line L1 and the second line L2 may extend onto the first surface of the resin layer 110 while being in direct contact with the side surface of the corresponding inorganic insulating stack IIL.

Referring to FIG. 14C, the light-emitting diode LED may be formed on each of the first pixel circuit layer PCL1 and the second pixel circuit layer PCL2 described with reference to FIG. 14B. The light-emitting diode LED may include an inorganic light-emitting diode.

Referring to FIG. 14D, the protective layer 300 may be formed on the light-emitting diode LED. The protective layer 300 may include the same material as described with reference to FIG. 9. The protective layer 300 may directly contact the resin layer 110 during the process. The protective layer 300 may be formed by depositing a material (for example, an elastomer) included in the protective layer 300 and curing the material. The curing process may be performed by using heat or light, such as ultraviolet (UV) rays.

A carrier film 500 may be formed on the protective layer 300. In one or more other embodiments, an adhesion layer may further be arranged between the protective layer 300 and the carrier film 500. The carrier film 500 may protect the protective layer 300 from being affected by scratching, stamping, or the like, which may occur during the process. For example, the carrier film 500 may include an insulating material.

Referring to FIG. 14E, after flipping the structure according to the process of FIG. 14D upside down, the substrate 100 may be removed from the resin layer 110. adhesion between the substrate 100 and the resin layer 110 may be reduced by irradiating a laser beam onto another surface of the substrate 100, which is the opposite to a surface of the substrate 100 that is in contact with the resin layer 110. Accordingly, the substrate 100 may be separated and removed from the resin layer 110. However, it is only an example. The method of removing the substrate 100 may be variously modified.

Referring to FIG. 14F, the resin layer 110 may be removed. The resin layer 110 may be removed by dry etching. As the resin layer 110 is removed, surfaces of the first pixel circuit layer PCL1 and the second pixel circuit layer PC2 (for example, surfaces that are the opposite to surfaces toward the light-emitting diodes LED) may be exposed. For example, one surface of the inorganic insulating stack IIL of each of the first pixel circuit layer PCL1 and the second pixel circuit layer PCL2 (for example, a surface that is the opposite to a surface toward the first organic insulating layer 121), one surface of one portion of the first organic insulating layer 121 of each of the first pixel circuit layer PCL1 and the second pixel circuit layer PCL2, and one surface of one portion of each of the first line L1 and the second line L2 may be exposed. The one surface of the inorganic insulating stack IIL, the one surface of the one portion of the first organic insulating layer 121, and the one surface of the one portion of each of the first line L1 and the second line L2 may be coplanar.

Referring to FIG. 14G, the connection line WL may be formed. The connection line WL may directly contact the one portion of the first line L1 and may directly contact the one portion of the second line L2, which are exposed to the outside. The connection line WL may be arranged in the second area 12 between the two adjacent first areas 11, and may extend from any one of the two adjacent first areas 11 toward the other (e.g., in a direction toward the other).

According to one or more embodiments, the connection line WL may include liquid metal or a conductive composite material including a metal nanostructure, an elastic polymer, and/or an elastomer. The connection line WL may be formed by vacuum deposition, printing, coating, etc.

Referring to FIG. 14H, the base layer 400 may be formed on the connection line WL. The base layer 400 may be arranged to cover the connection line WL. The base layer 400 may include the same material as described with reference to FIG. 9. The base layer 400 may support the elements of the display panel 10 (see FIG. 9), and may absorb stress that may occur when the display panel 10 (see FIG. 9) is stretched.

The structure of FIG. 14H may be flipped again, thereafter, as illustrated in FIG. 9, and the display panel 10 as illustrated in FIG. 9 may be formed by removing the carrier film 500. The carrier film 500 (see FIG. 14H) may be removed by using an exfoliating tape.

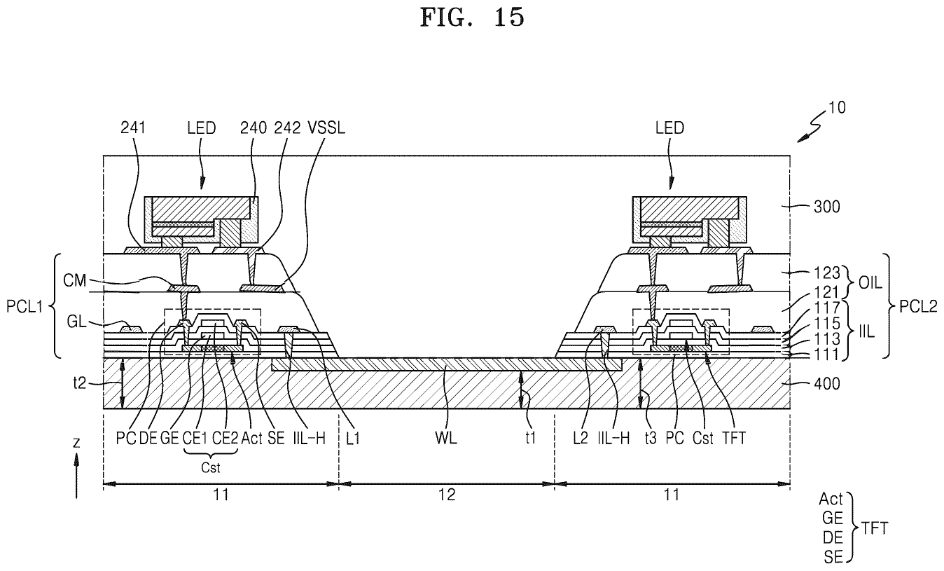

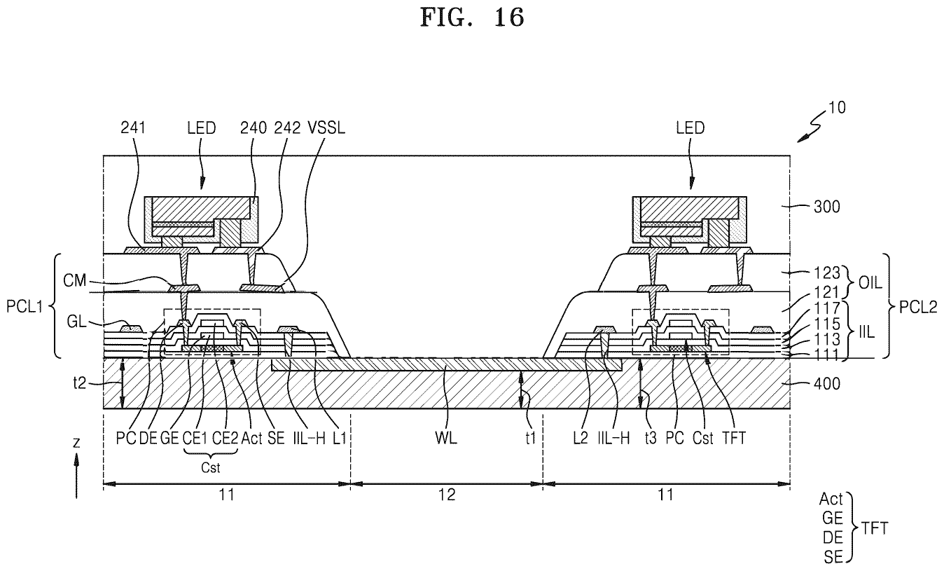

FIGS. 15 and 16 are each a cross-sectional view of a portion of the display panel 10 according to one or more embodiments. The embodiments illustrated in FIGS. 15 and 16 may be substantially the same as those described above with reference to FIG. 9, except for a connection structure of the first line L1, the second line L2, and the connection line WL, and except for structures of the first and second organic insulating layers 121 and 123. Thus, the elements of FIGS. 15 and 16 that are referred to by the same reference numerals as in FIG. 9 are not repeatedly described, and hereinafter, different aspects are mainly described.

Referring to FIGS. 15 and 16, the connection line WL may be embedded in the base layer 400, and thus, a first thickness t1 of a first portion of the base layer 400 overlapping the connection line WL may be less than a second thickness t2 and a third thickness t3 respectively of a second portion and a third portion of the base layer 400 respectively overlapping the first and second pixel circuit layers PCL1 and PCL. Both side portions of the connection line WL may extend to overlap the inorganic insulating stack IIL of each of the first and second pixel circuit layers PCL1 and PCL2. Each side portion of the connection line WL may directly contact a surface (for example, a surface toward the base layer 400, that is, a bottom surface) of the inorganic insulating stack IIL.

Each of the first line L1 and the second line L2 may be arranged on the corresponding inorganic insulating stack IIL, and may not extend across a side surface of the inorganic insulating stack IIL onto the connection line WL. The first line L1 may be electrically connected to the connection line WL through a contact hole IIL-H passing through the inorganic insulating stack IIL of the first pixel circuit layer PCL1. The second line L2 may be electrically connected to the connection line WL through another contact hole IIL-H passing through the inorganic insulating stack IIL of the second pixel circuit layer PCL2. The contact hole IIL-H may be at least partially filled with a portion of the connection line WL. Each of the contact hole IIL-H between the first line L1 and the inorganic insulating stack IIL, and the contact hole IIL-H between the second line L2 and the inorganic insulating stack IIL, may be at least partially filled with the portion of the connection line WL, for example, a material corresponding to the connection line WL.

According to one or more embodiments, the width of the organic insulating layer OIL having an isolated shape to correspond to the first area 11 may be the same as or less than the width of the inorganic insulating stack IIL. As illustrated in FIG. 15, the width of the organic insulating layer OIL may be less than the width of the inorganic insulating stack IIL. For example, the first organic insulating layer 121 and the second organic insulating layer 123 may not extend across the side surface of the inorganic insulating stack IIL onto the connection line WL. A side surface of the first organic insulating layer 121 may meet an upper surface of the inorganic insulating stack IIL.

According to one or more other embodiments, the width of the organic insulating layer OIL may be greater than the width of the inorganic insulating stack IIL, as illustrated in FIG. 16. For example, the first organic insulating layer 121 may extend across the side surface of the inorganic insulating stack IIL onto the connection line WL. The first organic insulating layer 121 may extend across the side surface of the inorganic insulating stack IIL onto the connection line WL.

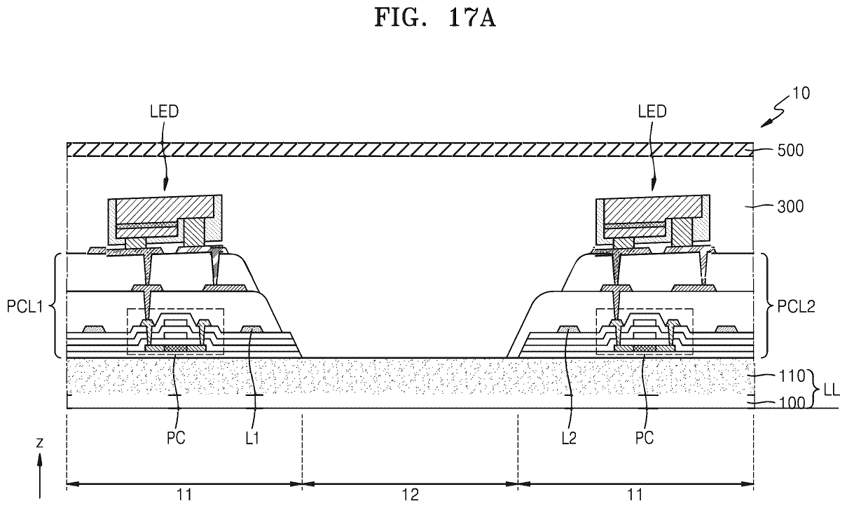

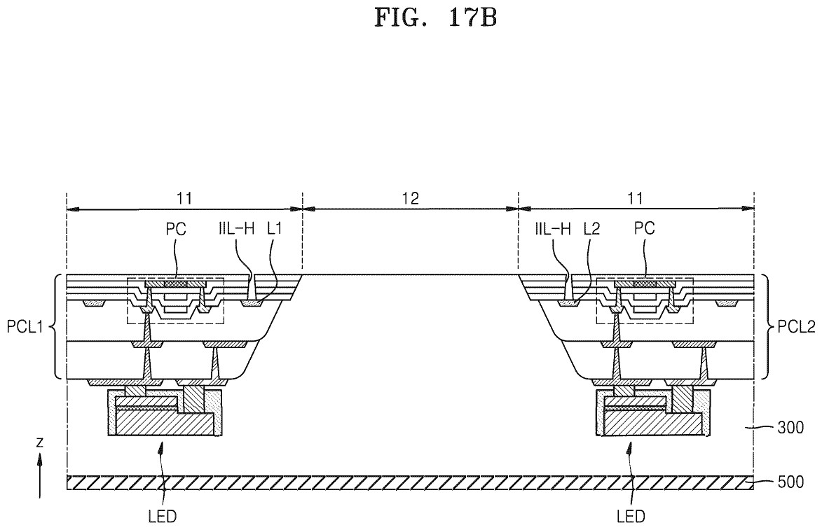

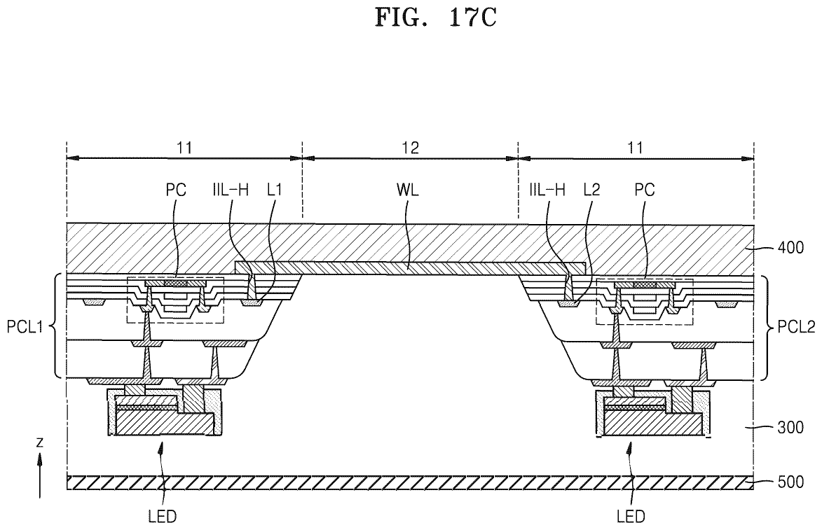

FIGS. 17A to 17C are cross-sectional views for describing a process of manufacturing the display panel 10, according to one or more embodiments.

Referring to FIG. 17A, the carrier layer LL including the substrate 100 and the resin layer 110 arranged on the substrate 100 may be prepared. The first pixel circuit layer PCL1 and the second pixel circuit layer PCL2 may be formed on the carrier layer LL, and the light-emitting diode LED may be formed on each of the first and second pixel circuit layers PCL1 and PCL2. The protective layer 300 may cover the light-emitting diode LED, and may be in contact with a portion of the carrier layer LL.

The carrier film 500 may be formed on the protective layer 300. A detailed process of forming the first and second pixel circuit layers PCL1 and PCL2, the light-emitting diodes LED, the protective layer 300, and the carrier film 500 is the same as described above with reference to FIGS. 14A to 14D.

FIG. 17A illustrates that the width of the first organic insulating layer 121 may be less than the width of the inorganic insulating stack IIL. However, the disclosure is not limited thereto. According to one or more other embodiments, the width of the first organic insulating layer 121 may be greater than the width of the inorganic insulating stack IIL as illustrated in FIG. 16.

Referring to FIG. 17B, after flipping the structure according to the process of FIG. 17A upside down, the carrier layer LL may be removed. The process of removing the carrier layer LL may include a process of irradiating a laser beam onto another surface of the substrate 100 that is the opposite to a surface of the substrate 100 that is in contact with the resin layer 110, and also may include a process of removing the resin layer 110 through etching.

By removing the carrier layer LL, surfaces of the first and second pixel circuit layers PCL1 and PCL2 (for example, surfaces that are the opposite to surfaces toward the light-emitting diodes LED) may be exposed. For example, one surface of the inorganic insulating stack IIL of each of the first and second pixel circuit layers PCL1 and PCL2 (for example, a surface that is the opposite to a surface toward the first organic insulating layer 121) may be exposed.

Thereafter, the contact hole IIL-H may be formed in the inorganic insulating stack IIL. The contact hole IIL-H formed in the inorganic insulating stack IIL of the first pixel circuit layer PCL1 may be spatially connected to the first line L1. The contact hole IIL-H formed in the inorganic insulating stack IIL of the second pixel circuit layer PCL2 may be spatially connected to the second line L2.

Referring to FIG. 17C, the connection line WL may be formed. The connection line WL may be connected to the first line L1 through the contact hole IIL-H of the inorganic insulating stack IIL of the first pixel circuit layer PCL1, and may be connected to the second line L2 through the contact hole IIL-H of the inorganic insulating stack IIL of the second pixel circuit layer PCL2. The connection line WL may include liquid metal or a conductive composite material including a metal nanostructure, an elastic polymer, and/or an elastomer. The connection line WL may be formed by vacuum deposition, printing, coating, etc.

The base layer 400 may be formed on the connection line WL. The base layer 400 may be arranged to cover the connection line WL. The base layer 400 may include the same material as described with reference to FIG. 9.

The structure of FIG. 17C may be flipped again, and by removing the carrier film 500, the display panel 10 as illustrated in FIG. 15 may be formed.

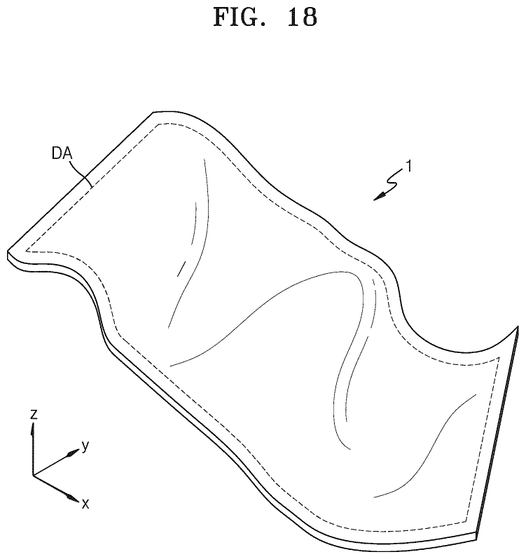

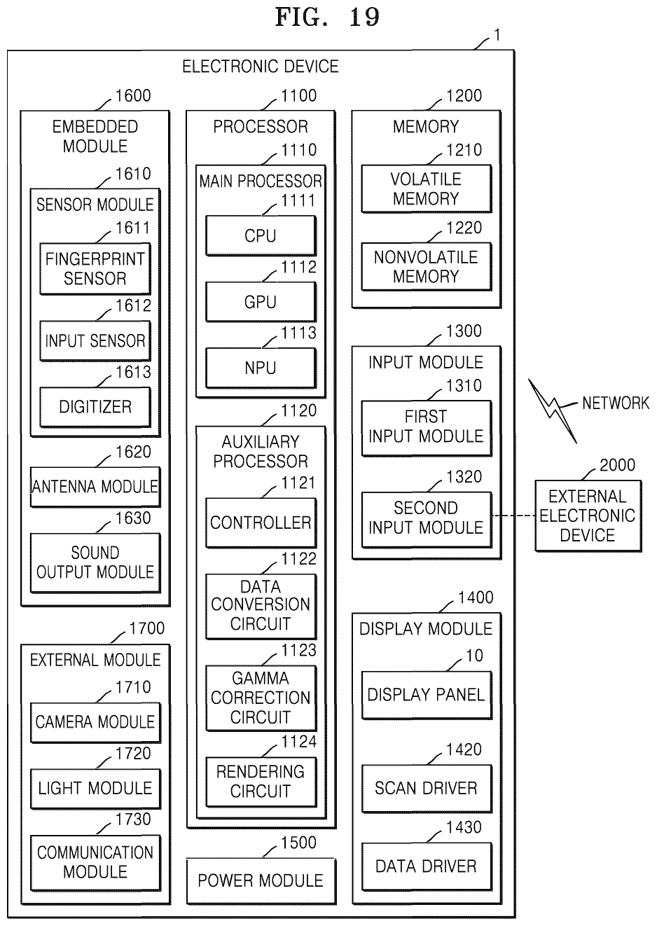

FIG. 18 is a schematic perspective view of an electronic device 1 including the display panel 10 according to one or more embodiments, and FIG. 19 is a block diagram of the electronic device 1 including the display panel 10 according to one or more embodiments.

Referring to FIG. 18, the electronic device 1 may be freely and three-dimensionally deformed, and may provide a three-dimensional image surface through the display area DA. The electronic device 1 being freely and three-dimensionally deformed may be different from an operation of an electronic device having a rollable display panel, whereby only a portion of a rolled display area is seen by a user, and as another portion of the rolled display area is unrolled, the entire display area is seen by the user (or the entire unrolled display area is seen by a user, and as the display area is rolled, only a portion of the display area is seen by the user). When the electronic device 1 according to embodiments is deformed in an x direction, a y direction, and/or a z direction, the entire display area DA may be deformed, for example, to have an increased area or again a decreased area.

Referring to FIG. 19, the electronic device 1 may include a processor 1100, a memory 1200, an input module 1300, a display module 1400, a power module 1500, an embedded module 1600, and an external module 1700. According to one or more embodiments, the electronic device 1 may omit at least one of the components described above or may further include one or more different components. According to one or more embodiments, some of the components described above (for example, the embedded module 1600) may be integrated into another component (for example, the display module 1400).

The processor 1100 may execute software to control at least another component (for example, a hardware or software component) of the electronic device 1 connected to the processor 1100 and may perform various data processing or calculation operations. According to one or more embodiments, as at least one of the data processing or calculation operations, the processor 1100 may store a command or data received from other components (e.g., the input module 1300, a sensor module 1610 or a communication module 1730) in a volatile memory 1210, may process the command or the data stored in the volatile memory 1210, and may store resultant data in a nonvolatile memory 1220.

The processor 1100 may include a main processor 1110 and an auxiliary processor 1120. The main processor 1110 may include at least one of a central processing unit (CPU) 1111 or an application processor (AP). The main processor 1110 may further include at least one of a graphics processing unit (GPU) 1112, a communication processor (CP), or an image signal processor (ISP). The main processor 1110 may further include a neural processing unit (NPU) 1113. The NPU 1113 may be processor specialized for processing an artificial intelligence (AI) model, and the AI model may be generated through machine learning. The AI model may include a plurality of artificial neural network layers. The artificial neural network may include a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or one of combinations of at least two thereof, but is not limited thereto. The AI model may include a software structure additionally or alternatively, in addition to a hardware structure. At least two of the processing units and the processor described above may be realized as one integrated component (for example, a single chip) or each may be realized as a separate component (for example, a plurality of chips).

The auxiliary processor 1120 may include a controller 1121. The controller 1121 may include an interface conversion circuit and a timing control circuit. The controller 1121 may receive an image signal from the main processor 1110 and may output image data by converting a data format of the image signal to correspond to the interface specifications with respect to the display module 1400. The controller 1121 may output various control signals needed to drive the display module 1400.

The auxiliary processor 1120 may further include a data-processing circuit, such as a data conversion circuit 1122, a gamma correction circuit 1123, a rendering circuit 1124, etc. The data conversion circuit 1122 may receive the image data from the controller 1121, may compensate for the image data such that an image is displayed by a desired brightness according to the feature of the electronic device 1 or the user's setting, or may convert the image data for power consumption reduction or afterimage compensation. The gamma correction circuit 1123 may convert the image data or a gamma reference voltage such that the image displayed on the electronic device 1 has a desired gamma characteristic. The rendering circuit 1124 may receive the image data from the controller 1121, and may render the image data by considering pixel arrangement of the display panel 10 implemented in the electronic device 1, etc. At least one of the data conversion circuit 1122, the gamma correction circuit 1123, or the rendering circuit 1124 may be integrated into another component (for example, the main processor 1110 or the controller 1121). According to one or more embodiments, the auxiliary processor 1120 may be integrated into a data driver 1430.

The memory 1200 may store various data used by at least one component (for example, the processor 1100 and/or the sensor module 1610) of the electronic device 1 and input data or output data with respect to a command with respect to the data. The memory 1200 may include at least one of the volatile memory 1210 or the nonvolatile memory 1220.

The input module 1300 may receive, from the outside of the electronic device 1 (for example, a user or an external electronic device 2000), a command or data to be used for the component (for example, the processor 1100, the sensor module 1610, or a sound output module 1630) of the electronic device 1.

The input module 1300 may include a first input module 1310 into which a command or data is input from a user and a second input module 1320 into which a command or data is input from the external electronic device 2000.

The first input module 1310 may include a microphone, a mouse, a keyboard, or a pen (for example, a passive pen or an active pen). The first input module 1310 may include a mechanical input device, such as a button, a dome switch, a jog wheel, a jog switch, etc. on a rear surface or a side surface of the electronic device 1 or a touch input device. The touch input device may include a touch screen layer of the display panel 10.

The second input module 1320 may be connected to various types of external electronic devices 2000 connected to the electronic device 1 in a wired or wireless fashion. According to one or more embodiments, the second input module 1320 may include a high definition multimedia interface (HDMI), a universal serial bus (USB) interface, a secure digital (SD) card interface, or an audio interface. The second input module 1320 may include a connector for physically connecting the electronic device 1 to the external electronic device 2000, for example, an HDMI connector, a USB connector, an SD card connector, or an audio connector (for example, a headphone connector). The electronic device 1 may perform an appropriate control operation with respect to the external electronic device 2000 connected thereto, when the external electronic device 2000 is connected to the second input module 1320.

The display module 1400 may visually provide information to a user. The display module 1400 may include the display panel 10, a scan driver 1420, and a data driver 1430.

The display panel 10 may display (output) information processed by the electronic device 1. The display panel 10 may display execution screen information of an application driven by the electronic device 1 or may display user interface (UI) or graphics UI (GUI) information according to the execution screen information.

The scan driver 1420 may be mounted on the display panel 10 as a driving chip. Alternatively, the scan driver 1420 may be directly formed on the display panel 10. For example, the scan driver 1420 may include an amorphous silicon thin-film transistor (TFT) gate (ASG) driver circuit, a low temperature polycrystalline silicon (LTPS) TFT gate driver circuit, or an oxide semiconductor TFT gate (OSG) driver circuit, which is embedded in the display panel 10. The scan driver 1420 may receive a control signal from the controller 1121 and may output scan signals to the display panel 10 in response to the control signal.

The display panel 10 may further include an emission control driver. The emission control driver may output an emission control signal to the display panel 10 in response to a control signal received from the controller 1121. The emission control driver may be separately formed from the scan driver 1420 or may be integrated into the scan driver 1420.

The data driver 1430 may receive a control signal from the controller 1121 and may output data voltages to the display panel 10 after converting image data into the data voltages in the form of analog voltages in response to the control signal.

The data driver 1430 may be integrated into some components of the auxiliary processor 1120. For example, the data driver 1430 may be provided as a timing controller embedded driver integrated circuit (IC) including the controller 1121.

The power module 1500 may supply power to the components of the electronic device 1. The power module 1500 may include a battery for charging a power voltage. Also, the power module 1500 may include a connection port, and the connection port may be included in the second input module 1320, to which an external charger for supplying power is connected to charge the battery. Alternatively, the power module 1500 may include a wireless power transmission and reception member for charging the battery wirelessly. The wireless power transmission and reception member may include a plurality of antenna radiators in the form of coils. The power module 1500 may include a power management IC (PMIC). The PMIC may supply power optimized for each of the components of the electronic device 1.

The electronic device 1 may further include the embedded module 1600 and the external module 1700. The embedded module 1600 may include the sensor module 1610, an antenna module 1620, and the sound output module 1630. The external module 1700 may include a camera module 1710, a light module 1720, and/or a communication module 1730.

The sensor module 1610 may include touch electrodes of the touch screen layer of the display panel 10 and a touch sensor driver. The sensor module 1610 may sense an input by a human body of a user or a pen and may generate an electrical signal or a data value corresponding to the input. The sensor module 1610 may include at least one of a fingerprint sensor 1611, an input sensor 1612, or a digitizer 1613.

The fingerprint sensor 1611 may generate a data value corresponding to the fingerprint of a user. The fingerprint sensor 1611 may include any one of a fingerprint sensor using an optical method and a fingerprint sensor using a capacitance method.

The input sensor 1612 may generate a data value corresponding to coordinate information of an input by a user's body or an input by a pen. The input sensor 1612 may generate a capacitance change amount based on the input into the data value. The input sensor 1612 may sense an input by a passive pen or transmit and receive data to and from an active pen.

The input sensor 1612 may measure biometric signals, such as blood pressure, water, or body fat, etc. For example, when a user does not move for a corresponding time period while a body part of the user is being in contact with a sensor layer or a sensing panel, the input sensor 1612 may sense, based on a change of an electric field due to the body part, a biometric signal and may output information desired by the user to the display module 1400.

The digitizer 1613 may generate a data value corresponding to coordinate information of an input by a pen. The digitizer 1613 may generate an electromagnetic change amount based on the input into the data value. The digitizer 1613 may sense an input by a passive pen or transmit and receive data to and from an active pen.

According to one or more embodiments, at least one of the fingerprint sensor 1611, the input sensor 1612, or the digitizer 1613 may be embedded in the display panel 10. For example, at least one of the fingerprint sensor 1611, the input sensor 1612, or the digitizer 1613 may be formed by a process continued after a process of forming the pixel circuits and the light-emitting diodes of the display panel 10. Thus, the display panel 10 may function as one of the first and second input modules 1310 and 1320 configured to provide an input interface between the electronic device 1 and a user and may function as the display module 1400 configured to provide an output interface between the electronic device 1 and the user.

According to one or more embodiments, at least two of the fingerprint sensor 1611, the input sensor 1612, and the digitizer 1613 may be formed to be integrated into one sensing panel through the same process. The sensing panel may be arranged between the display panel 10 and a window arranged above the display panel 10. However, the disclosure is not limited thereto.

The antenna module 1620 may include one or more antennas configured to transmit or receive a signal or power to or from the outside. According to one or more embodiments, the communication module 1730 may transmit or receive a signal to or from an external electronic device through an antenna appropriate for a communication method. An antenna pattern of the antenna module 1620 may be integrated into one component (for example, the display panel 10) of the display module 1400, the input sensor 1612, or the like.

The sound output module 1630 may be configured to output a sound signal to the outside of the electronic device 1 and output sound data received from the communication module 1730 or stored in the memory 1200 according to call signal reception, a calling mode or a recording mode, a voice recognition mode, a broadcasting reception mode, etc. The sound output module 1630 may output a sound signal related to functions (for example, a call signal reception sound, a message reception sound, etc.) performed by the electronic device 1. The sound output module 1630 may include a receiver and a speaker. At least one of the receiver or the speaker may include a sound generation device which is attached below the display panel 10 and vibrates the display panel 10 to output sound. The sound generation device may include a piezoelectric element or a piezoelectric actuator contracting or expanding according to an electrical signal or an exciter vibrating the display panel 10 by generating a magnetic force by using a voice coil.

The camera module 1710 may capture a still image and a motion image.

According to one or more embodiments, the camera module 1710 may include one or more lenses, image sensors, or image signal processors. The camera module 1710 may further include an infrared camera configured to measure whether or not a user exits, a location of the user, the user's sight, etc.

The light module 1720 may output a signal to notify an event occurrence by using light of a light source or may provide light for obtaining an image. Here, examples of the event occurrence may include message reception, call signal reception, unanswered calls, notification, schedule notification, email reception, battery charge amount information notification, etc. The light module 1720 may include a light-emitting diode or a xenon lamp. The light module 1720 may emit light of a single color or a plurality of colors through a front surface or a rear surface of the electronic device 1. The light module 1720 may operate in synchronization with the camera module 1710 or separately from the camera module 1710.

The communication module 1730 may establish a wired or wireless communication channel between the electronic device 1 and the external electronic device 2000 and support communication through the established communication channel. The communication module 1730 may include any one or all of a wireless communication module, such as a cellular communication module, a near-field communication (NFC) module, or a global navigation satellite system (GNSS) communication module, and a wired communication module, such as a local area network (LAN) communication module or a power line communication module. The communication module 1730 may transmit and receive a wireless signal on the Internet network by using at least one of a wireless LAN (WLAN), wireless-fidelity/Wi-Fi® (Wi-Fi® being a registered trademark of the non-profit Wi-Fi Alliance), Wi-Fi Direct™ (Wi-Fi Direct™ being a registered trademark of the non-profit Wi-Fi Alliance), or a digital living network alliance (DLNA). Also, the communication module 1730 may support short-range wireless communication by using at least one of a Bluetooth® (Bluetooth® being a registered trademark of Bluetooth Sig, Inc., Kirkland, WA), radio frequency identification (RFID), infrared data association (IrDA), ultra wideband (UWB), Zigbee® (ZigBee® being a registered trademark of Connectivity Standards Alliance, CA), NFC, Wi-Fi®, Wi-Fi Direct™, or a wireless USB. Various communication modules 1730 described above may be realized as one chip or each may be realized as a separate chip.

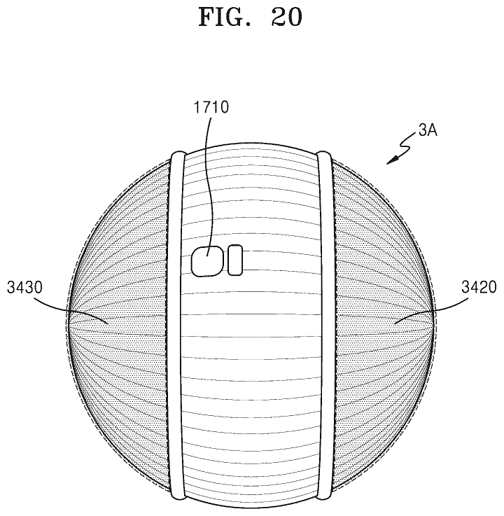

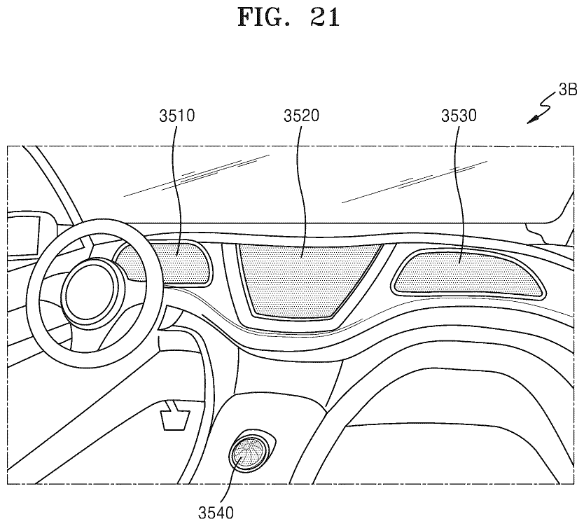

According to one or more embodiments described with reference to FIGS. 18 and 19, the display panel 10 may be freely and three-dimensionally deformed and may be included in the electronic device 1 configured to provide an image surface which may be three-dimensionally deformed. However, the disclosure is not limited thereto. As illustrated in FIGS. 20 and 21, an electronic device may include an image provision area having a fixed shape, and in a process of manufacturing the electronic device, a display panel may be arranged in the image provision area of the electronic device described above, while the display panel 10 may be fixed to the electronic device 1 in a three-dimensionally deformed state.

FIGS. 20 and 21 are each a perspective view of an electronic device according to one or more embodiments.

FIG. 20 illustrates a robot as another electronic device 3A, according to one or more embodiments. The robot may recognize a movement or an object by using the camera module 1710 and may display a corresponding image for a user through displays 3420 and 3430. According to some embodiments, the display panels according to one or more embodiments may be stretched in various directions as described above, and thus, may be assembled into a frame of the electronic device 3A while being three-dimensionally stretched along a body frame having a semicircular shape and may form the displays 3420 and 3430.

FIG. 21 illustrates a vehicle display device as another electronic device 3B according to one or more embodiments. The vehicle display device may include a cluster 3510, a center information display (CID) 3520, and/or a co-driver display 3530. The display panel according to one or more embodiments may be stretched in various directions, and thus, may not be restricted by the shape of an internal frame of a vehicle and may be used for the cluster 3510, the CID 3520, and/or the co-driver display 3530.

FIG. 21 illustrates that the cluster 3510, the CID 3520, and/or the co-driver display 3530 are/is (a) separate device(s) from each other. However, the disclosure is not limited thereto. According to one or more other embodiments, two or more selected from among the cluster 3510, the CID 3520, and/or the co-driver display 3530 may be integrally connected.

According to some embodiments, the vehicle display device may include a button 3540 configured to display a corresponding image. A semi-circular button 3540 may sense a touch input of a user (for example, a driver) in a z direction or a-z direction.

FIGS. 20 and 21 illustrate that the electronic devices 3A and 3B are used for the robot and the vehicle, respectively. However, the disclosure is not limited thereto. The electronic device according to the disclosure may include electronic devices for various purposes, such as a commercial electronic device, an office electronic device, an educational electronic device, a wearable electronic device, a medical electronic device, etc. In other words, the display panel according to one or more embodiments may be included in various electronic devices including an area for providing an image.

According to some embodiments, the display panel and the electronic device having improved flexibility and realizing an excellent quality image may be provided.

The effects described above are examples, and the effects of the disclosure are not limited thereto.

It should be understood that embodiments described herein should be considered in a descriptive sense only and not for purposes of limitation. Descriptions of aspects within each embodiment should typically be considered as available for other similar aspects in other embodiments. While one or more embodiments have been described with reference to the figures, it will be understood by one of ordinary skill in the art that various changes in form and details may be made therein without departing from the spirit and scope as defined by the following claims, with functional equivalents thereof to be included therein.

What is claimed is:

1. A display panel comprising:
a base layer comprising a first surface, and a second surface that is opposite to the first surface;
a first pixel circuit layer above the first surface of the base layer, and comprising a first transistor;
a second pixel circuit layer above the first surface of the base layer, apart from the first pixel circuit layer, and comprising a second transistor;
a first light-emitting diode above the first pixel circuit layer, and electrically connected to the first transistor;
a second light-emitting diode above the second pixel circuit layer, and electrically connected to the second transistor;
a first line electrically connected to the first transistor;
a second line electrically connected to the second transistor; and
a connection line for electrically connecting the first line to the second line,
wherein each of the first pixel circuit layer and the second pixel circuit layer includes insulating layers, the insulating layers comprises:
an inorganic insulating stack comprising inorganic insulating layers; and
an organic insulating layer above the inorganic insulating stack, and
wherein the first line extends across the inorganic insulating stack of the first pixel circuit layer toward the connection line and directly contact the connection line.

2. The display panel of claim 1, wherein a first thickness of a first portion of the base layer overlapping the connection line is less than a second thickness of a second portion of the base layer overlapping a pixel circuit of the first pixel circuit layer.

3. The display panel of claim 1, wherein the organic insulating layer comprises:
a first organic insulating layer on the inorganic insulating stack of the first pixel circuit layer; and
a second organic insulating layer on the first organic insulating layer.

4. The display panel of claim 3, wherein the first organic insulating layer of the first pixel circuit layer overlaps a first contact point of the first line and the connection line.

5. The display panel of claim 3, wherein the organic insulating layer further comprises a third organic insulating layer between the inorganic insulating stack and the first organic insulating layer, and covering a side surface of the inorganic insulating stack, and
wherein a portion of the first line is between the third organic insulating layer and the first organic insulating layer.

6. The display panel of claim 3, wherein a width of the first organic insulating layer is greater than a width of the inorganic insulating stack.

7. The display panel of claim 3, wherein the first organic insulating layer contacts an upper surface of the connection line.

8. The display panel of claim 1, wherein a first contact point of the first line and the connection line, and a second contact point of the second line and the connection line, are between the inorganic insulating stack of the first pixel circuit layer and the inorganic insulating stack of the second pixel circuit layer.

9. The display panel of claim 1, wherein a first contact point of the first line and the connection line does not overlap the inorganic insulating stack of the first pixel circuit layer, and
wherein a second contact point of the second line and the connection line does not overlap the inorganic insulating stack of the second pixel circuit layer.

10. The display panel of claim 1, further comprising a protective layer on the first light-emitting diode and the second light-emitting diode, and directly contacting the connection line.

11. The display panel of claim 10, wherein the protective layer and the base layer comprise a same material.

12. The display panel of claim 1, further comprising:
a first area in which the first pixel circuit layer and the first light-emitting diode are arranged, and having a first elongation; and
a second area in which the connection line is arranged, and having a second elongation that is greater than the first elongation.

13. An electronic device comprising a display panel comprising:
a base layer comprising a first surface, and a second surface that is opposite to the first surface;
a first pixel circuit layer above the first surface of the base layer, and comprising a first transistor and insulating layers;
a second pixel circuit layer above the first surface of the base layer, apart from the first pixel circuit layer, and comprising a second transistor and insulating layers;
a first light-emitting diode above the first pixel circuit layer, and electrically connected to the first transistor;
a second light-emitting diode above the second pixel circuit layer, and electrically connected to the second transistor;
a first line electrically connected to the first transistor;
a second line electrically connected to the second transistor; and
a connection line electrically connecting the first line to the second line,
wherein the insulating layers of each of the first pixel circuit layer and the second pixel circuit layer comprise:
an inorganic insulating stack comprising inorganic insulating layers; and
an organic insulating layer above the inorganic insulating stack, and
wherein the first line is electrically connected to the connection line through a first contact hole passing through the inorganic insulating stack of the first pixel circuit layer and at least partially filled with a portion of the connection line.

14. The electronic device of claim 13, wherein a width of the organic insulating layer of the first pixel circuit layer is less than or equal to a width of the inorganic insulating stack of the first pixel circuit layer.

15. The electronic device of claim 13, wherein the second line is electrically connected to the connection line through a second contact hole passing through the inorganic insulating stack of the second pixel circuit layer and at least partially filled with another portion of the connection line.

16. The electronic device of claim 13, further comprising a protective layer on the first light-emitting diode and the second light-emitting diode and directly contacting the connection line.

17. The electronic device of claim 16, wherein the protective layer and the base layer comprise a same material.

18. The electronic device of claim 13, further comprising:
a first area in which the first pixel circuit layer and the first light-emitting diode are arranged, and having a first elongation; and
a second area in which the connection line is arranged, and having a second elongation that is greater than the first elongation.

19. The electronic device of claim 13, wherein a first thickness of a first portion of the base layer overlapping the connection line is less than a second thickness of a second portion of the base layer overlapping a pixel circuit of the first pixel circuit layer.

20. The electronic device of claim 13, wherein the connection line comprises a first surface contacting the base layer, and a second surface opposite to the first surface and substantially coplanar with the first surface of the base layer.
